(19) United States
(12) Patent Application Publication
(10) Pub. No.: US 2024/0222227 A1
(43) Pub. Date: Jul. 4, 2024

(54) BACKSIDE CONTACTS FOR STACKED FIELD EFFECT TRANSISTORS

(71) Applicant: INTERNATIONAL BUSINESS MACHINES CORPORATION, ARMONK, NY (US)

(72) Inventors: Ruilong Xie, Niskayuna, NY (US); Julien Frougier, Albany, NY (US); Min Gyu Sung, Latham, NY (US); Chanro Park, Clifton Park, NY (US); Juntao Li, Cohoes, NY (US)

(21) Appl. No.: 18/089,655

(22) Filed: Dec. 28, 2022

(51) Int. Cl. H01L 23/48; H01L 21/8234; H01L 29/06; H01L 29/417; H01L 29/786

(52) U.S. Cl. CPC H01L 23/481; H01L 21/823412; H01L 21/823418; H01L 21/823475; H01L 29/0673; H01L 29/41733; H01L 29/78696

(57) ABSTRACT

Embodiments are disclosed for a semiconductor device and a method for fabrication. The device includes a first gate, having a top FET that is disposed above a bottom FET, and in electrical contact with a top source/drain epitaxial (S/D epi) and a back end of line (BEOL) interconnect. Additionally, the device includes the bottom FET. The bottom FET is in electrical contact with a bottom S/D epi. Further, a shallow backside contact is in electrical contact with the bottom S/D epi. Additionally, the device includes a deep via that is in electrical contact with the BEOL interconnect and the shallow backside contact. The deep via and the shallow backside contact provide a conductive path between the BEOL interconnect and the bottom S/D epi.

### BACKGROUND

The present disclosure relates to backside contacts, and more specifically, to backside contacts for stacked field effect transistor (FET) semiconductor devices.

Semiconductor devices (devices) can be used in computer processors, computer memories, and the like. These devices include transistors, such as field effect transistors (FET), which enable the processing and data storage of a computer processor and memory by controlling current flowing from source to drain. The FET controls current flow by using an electric field. Some semiconductor devices include stacked FETs, i.e., two layers, with each layer having metal wiring and contacts to the frontside and backside of the device.

The term, frontside, refers to the back end of line (BEOL) interconnect, which includes signal wiring for the semiconductor device. The signal wiring can include the logic circuitry for the device. With respect to the backside, the term specifically refers to the backside interconnect, which can include wiring for power to the device (i.e., Vss/Vdd).

Semiconductor devices are fabricated on wafers. Accordingly, in discussing the fabrication of wafers having semiconductor devices, it can be useful to describe the location of elements of the wafer using reference points. More specifically, the backside and the frontside provide reference points to describe the relative locations of specific elements of the wafer. For example, the backside is “below” the frontside. Additionally, wafers include a middle of line (MOL), having wiring and contacts. In these descriptions, the BEOL interconnect (frontside) is above the top layer of FETS, which is above the MOL, which is above the bottom layer of FETs, which is above the backside interconnect. However, references to relative locations herein (e.g., above, below beneath, left of, and the like) are mere examples, and non-limiting with respect to any specific disposition described.

As stated previously, FETs can be stacked in top and bottom layers. Accordingly, the top layer of the stacked FETs is disposed between the BEOL and the bottom source/drain (S/D), which is the S/D of the FET in the bottom layer. As such, the top layer FET blocks the potential path for wiring between the bottom S/D and the BEOL. Further, using a backside contact for the wiring can potentially short to the Vss/Vdd of the backside. Thus, it can be challenging to route wiring between the bottom S/D and the signal wiring of the BEOL.

### SUMMARY

Embodiments are disclosed for a semiconductor device. The device includes a first gate stack, having a top FET that is disposed above a bottom FET, and in electrical contact with a top source/drain epitaxial (S/D epi) and a back end of line (BEOL) interconnect. Additionally, the device includes the bottom FET. The bottom FET is in electrical contact with a bottom S/D epi. Further, a shallow backside contact is in electrical contact with the bottom S/D epi. Additionally, the device includes a deep via that is in electrical contact with the BEOL interconnect and the shallow backside contact. The deep via and the shallow backside contact provide a conductive path between the BEOL interconnect and the bottom S/D epi.

Embodiments are disclosed for a method for fabricating a semiconductor device. The method includes forming a first backside contact placeholder by forming a first recess under a region for a first bottom source/drain epitaxial (S/D epi) of a first gate stack having a first top S/D epi disposed above the first bottom S/D epi. The method also includes depositing a sacrificial dielectric material in the first recess. Additionally, the method includes forming a first gate cut between the first gate stack and a second gate stack. Further, the method includes filling the first gate cut with a bi-layer dielectric fill. The method additionally includes forming a first deep via through an inner dielectric of the bi-layer dielectric fill, wherein the first deep via is in contact with the backside contact placeholder. The method also includes removing the first backside contact placeholder. Further, the method includes forming a shallow backside contact by generating a first deep backside contact by filling a region previously occupied by the removed backside contact placeholder with a conductive metal that is in electrical contact with the first deep via and the first bottom S/D epi, recessing the first deep backside contact, and forming a back end of line (BEOL) interconnect that is in electrical contact with the first deep via. The shallow backside contact does not short to a backside power rail (BSPR).

Further aspects of the present disclosure are directed toward computer program products with functionality similar to the functionality discussed above regarding the computer-implemented methods. The present summary is not intended to illustrate each aspect of every implementation of, and/or every embodiment of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 is a block diagram of an example computing environment, in accordance with some embodiments of the present disclosure.

FIG. 2A is a top view of an example semiconductor device, in accordance with some embodiments of the present disclosure.

FIG. 2B are vertical cross-section views of the example semiconductor device, in accordance with some embodiments of the present disclosure.

FIGS. 3A and 3B are parts of a process flow chart of a method for fabricating an example semiconductor device, in accordance with some embodiments of the present disclosure.

FIG. 4 is a block diagram of an overhead view of an example semiconductor device during fabrication, in accordance with some embodiments of the present disclosure.

FIGS. 5A, 5B, 5C, 5D, are example fabrication states of an example semiconductor device being fabricated, in accordance with some embodiments of the present disclosure.

FIG. 5E is a block diagram of an overhead view of an example semiconductor device during fabrication, in accordance with some embodiments of the present disclosure.

FIG. 5F is an example fabrication state of an example semiconductor device being fabricated, in accordance with some embodiments of the present disclosure.

FIG. 5G is a block diagram of an overhead view of an example semiconductor device during fabrication, in accordance with some embodiments of the present disclosure.

FIG. 5H is an example fabrication state of an example semiconductor device being fabricated, in accordance with some embodiments of the present disclosure.

FIG. 5I is a block diagram of an overhead view of an example semiconductor device during fabrication, in accordance with some embodiments of the present disclosure.

FIG. 5J is an example fabrication state of an example semiconductor device being fabricated, in accordance with some embodiments of the present disclosure.

FIG. 5K is a block diagram of an overhead view of an example semiconductor device during fabrication, in accordance with some embodiments of the present disclosure.

FIG. 5L is an example fabrication state of an example semiconductor device being fabricated, in accordance with some embodiments of the present disclosure.

FIG. 5M is a block diagram of an overhead view of an example semiconductor device during fabrication, in accordance with some embodiments of the present disclosure.

FIGS. 5N, 5O, 5P, 5Q, 5R, 5S are example fabrication states of an example semiconductor device being fabricated, in accordance with some embodiments of the present disclosure.

FIG. 5T is a block diagram of an overhead view of an example semiconductor device during fabrication, in accordance with some embodiments of the present disclosure.

FIGS. 5U, 5V, 5W are example fabrication states of an example semiconductor device being fabricated, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the embodiments described. On the contrary, the intention is to cover all modifications, equivalents, and alternatives falling within the spirit and scope of the present disclosure.

### DETAILED DESCRIPTION

As stated previously, it is possible to reduce congestion in the wiring of a stacked FET device with a buried power rail (BPR) and backside power distribution network (BSPDN) in the backside interconnect. However, it can be challenging to wire connections between the bottom S/D of stacked FETs and the signal wiring in the BEOL.

Accordingly, some embodiments of the present disclosure can fabricate a stacked FET semiconductor device having wiring between the bottom S/D epitaxials (epis) and the signal wiring of the BEOL. Such embodiments can include gate cut regions that are filled with bi-layer dielectrics, and located between top and bottom stacked FET cells. Additionally, such embodiments can include at least one deep via that is formed through an inner dielectric fill. This deep via connects to a shallow backside contact, which connects to a bottom S/D. Additionally, the reduced depth of the shallow backside contact may prevent a short with the backside power rail. Further, such embodiments include a backside contact with taller height compared to a shallow backside contact that wires a bottom S/D epi to a BPR. Additionally, such embodiments can include a deep via that wires a top S/D epi to the BPR. In this way, such embodiments can provide a stacked FET semiconductor device, having wiring routed between the bottom S/D epi and the BEOL, and between top S/D epi and the backside.

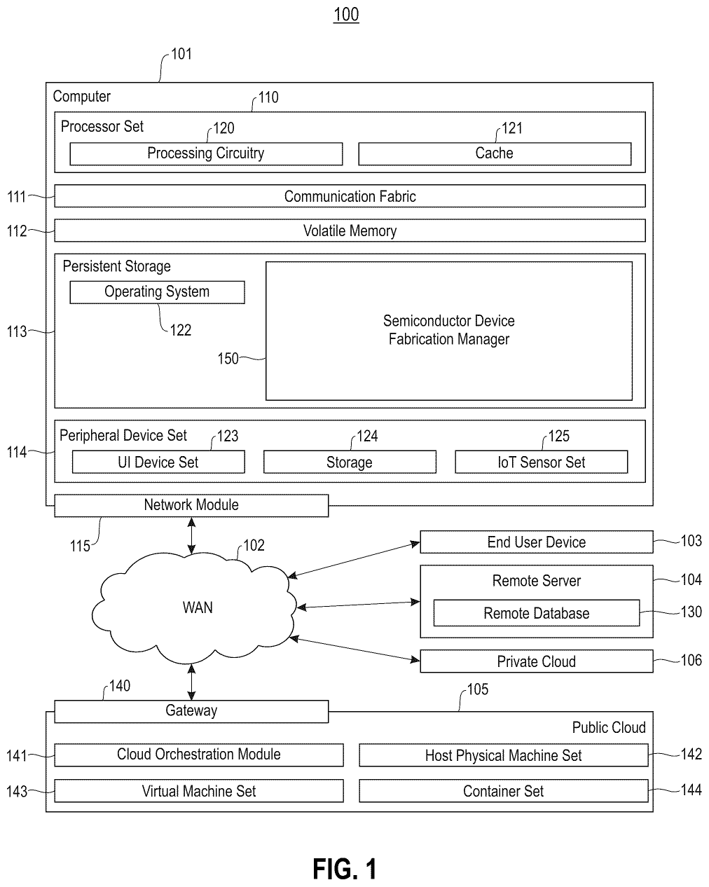

FIG. 1 is a block diagram of an example computing environment 100, in accordance with some embodiments of the present disclosure. Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as semiconductor device fabrication manager 150. In addition, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and semiconductor device fabrication manager 150, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in semiconductor device fabrication manager 150 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

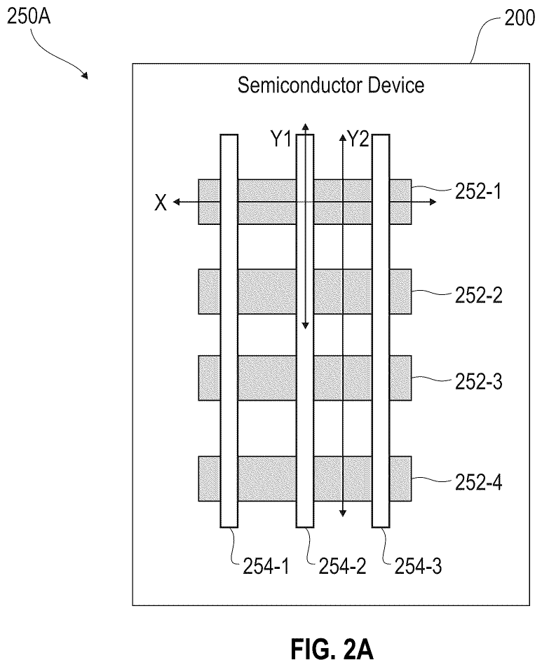

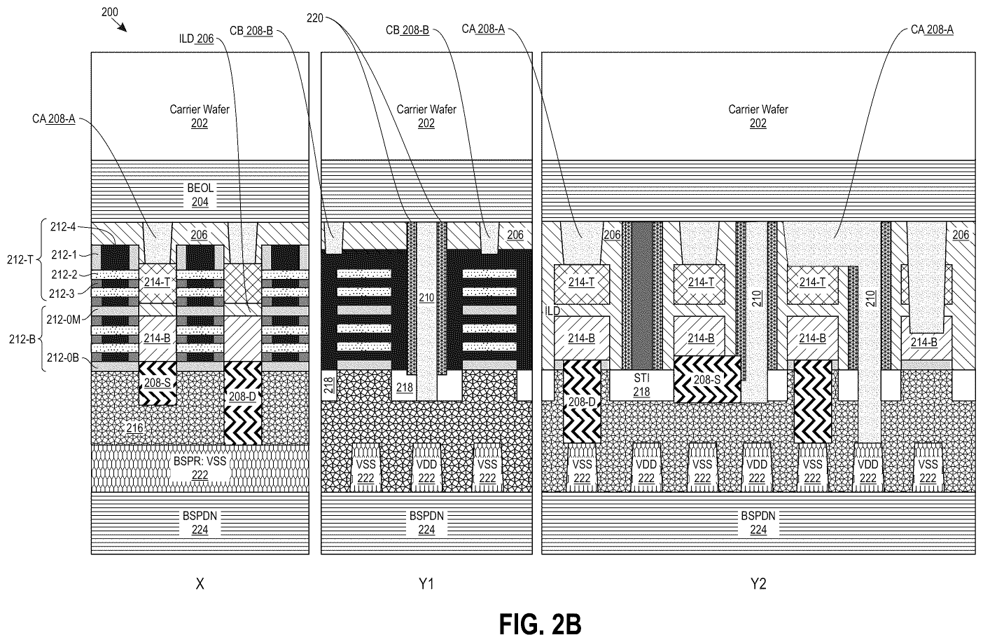

FIG. 2A is a top view 250 of an example semiconductor device 200, in accordance with some embodiments of the present disclosure. The overhead view 250A includes four device regions 252-1, 252-2, 252-3, 252-4 (collectively referred to as device regions 252) and three gate regions 254-1, 254-2, 254-3 (collectively referred to as gate regions 254). The device regions 252 represent the locations of the channels and S/D epis of the example semiconductor device 200. The gate regions 254 include a region on the intersecting device regions 252 having a stacked FET. Further, the overhead view 250A includes X, Y1, and Y2 cut lines, corresponding to cross-sectional views (described below) of the example semiconductor device 200.

FIG. 2B are vertical cross-section views of the example semiconductor device 200, in accordance with some embodiments of the present disclosure. As shown, the X cut line corresponds to the X view, which represents a cross-section of the device region 252-1, across gate regions 254-1, 254-2, 254-3. Additionally, the Y1 view represents a cross-section of the gate region 254-1, across device regions 252-1, 252-2; and, the Y2 view represents a cross-section of the intervening space between gate regions 254-2, 254-3 (i.e., along the device regions 252-1, 252-2, 252-3, 252-4).

Further, the views share features that are similar across the views. For example, the X, Y1, and Y2 views include a carrier wafer 202, BEOL 204, and ILD 206 on the frontside; and a backside ILD layer 216, BSPR 222, and BSPDN 224 on the backside. The carrier wafer 202 can represent a layer of silicon (Si) wafer. Further, the BEOL 204 can be composed of multiple layers of metal lines (including signal wiring and power rails) and vias (e.g., copper (Cu) based interconnects). With respect to the backside, the backside ILD layer 216 can be materials, such as SiO2, SiOC, SiN, low-k oxide, etc. The backside ILD layer 216 isolates the backside contacts from each other, and isolates the device layer from the BSPR 222. The BSPR 222 includes the source and drain power rails in the backside. The backside ILD layer 216 is backside interlayer dielectric (ILD) deposited from the backside of the wafer. Accordingly, the BSPR 222 and BSPDN 224 may power the example semiconductor device 200 when connected to a power source. The BSPDN 224 includes insulators (e.g., backside ILD), and back interconnect (e.g., backside metal wires, and backside metal vias).

As the X view represents the device region 252-1 across three gate regions 254, the X view includes three stacks of stacked FETs 212 (e.g., gate stacks), the two stacks of S/D epis 214 between these three gate stacks, contacts, and vias. The gate stacks include, from top to bottom, top FET 212-T and bottom FET 212-B (collectively referred to as stacked FETs 212). The ILD 206 may be dielectric materials such as, SiO2, SiN, SiBCN, SiOCN, SiOC, SiC, and the like. With respect to the gate stacks, the top and bottom FETs are separated from each other by a middle dielectric isolation (MDI) layer 212-0M. Similarly, the bottom FET 212-B is separated from the backside ILD layer 216 by a bottom dielectric isolation (BDI) layer 212-0B.

Additionally, the stacked FETs 212 can represent transistors having spacers 212-1, nanosheet channels 212-2, inner spacers 212-3, high-K metal gates (HK/MG) 212-4, and MDI layer 212-0M, and BDI layer 212-0B. The spacers 212-1 can include layers of dielectric material deposited and etched back to provide a spacing between the HK/MGs 212-4 and the contacts 208-A. Additionally, the nanosheet channels 212-2 can include nanosheets of a semiconductor material that can be conductive in a transistor, “on” state, or highly resistive in a transistor, “off” state. The conductivity of the nanosheet channels 212-2 can be controlled by the HK/MGs 212-4. Further, the inner spacers 212-3 can represent a dielectric material that provides a spacing between the HK/MGs 212-4 and the S/D epis 214. Additionally, the HK/MGs 212-4 can include a transistor gate electrode and gate dielectric of high k material (e.g., k=7 or more). The materials for the HK/MGs 212-4 may differ based on the type of device under construction (e.g., N-type or P-type FET).

Additionally, the X view includes two stacks of S/D epis 214 (top S/D epi 214-T and bottom S/D epi 214-B). The S/D epis 214 can be heavily doped epitaxial layers, such as boron-doped SiGe for p-type field effect transistors (PFETs) or phosphorus-doped Si for n-type FETs (NFETs). Further, the S/D epi stacks include, from top to bottom, contact 208-A, the top S/D epi 214-T, ILD 206 (isolating the top and bottom S/D epis from each other), and bottom S/D epi 214-B. Further, the S/D epi stacks differ below the bottom S/D epi 214-B. More specifically, the left S/D epi stack (between gate regions 254-1 and 254-2) also includes, a shallow backside contact 208-S, which is part of an interconnect (not shown) between the bottom S/D epi 214-B and the BEOL 204. According to some embodiments of the present disclosure, the shallow backside contact 208-S enables the example semiconductor device 200 to connect to this interconnect without risking a short to the BSPR 222. In contrast, the right S/D epi stack (between gate regions 254-2 and 254-3), the bottom S/D epi 214-B is connected to the BSPR 222 by a deep backside contact 208-D.

As stated previously, the Y1 view represents a cross-section of the gate region 254-1, across device regions 252-1, 252-2. Thus, the Y1 view represents the four FETs (i.e., two gate stacks), contacts, and vias at, and between, these device regions. The Y1 view structure includes (from top to bottom) a contact 208-B, the HK/MG 212-4, nanosheet channels 212-2, and an MDI 212-0M at the bottom of the top FET 212-T, and a BDI layer 212-0B at the bottom of the bottom FET 212-B. Further, the Y1 view structure includes an STI layer 218. Each of the gate stacks is located above, and isolated from, a BSPR 222-VSS.

Between the gate stacks, the Y1 view includes backside ILD layer 216 on each side of a deep via 210. The deep via 210 provides a conductive path (shown in view Y2) between a top S/D epi 214-T and the BSPR 222-VDD. Additionally, the backside ILD layer 216 isolates the deep via 210 from the gate stacks.

As stated previously, the Y2 view represents a cross-section of the example

semiconductor device 200 of device regions 252-1, 252-2, 252-3, 252-4 in the intervening space between gate regions 254-2, 254-3. More specifically, the Y2 view includes the S/D epis 214, contacts, and vias between the gates (i.e., the stacked FETs) at these gate regions. Accordingly, the Y2 view represents a cross S/D epi view of the four S/D epi stacks (i.e., top and bottom S/D epis), contacts, and vias that are located between the 16 stacked FETs 212 (eight stacks, four along each of gate regions 254-2, 254-3). The S/D epi stacks of the Y2 view are similar to the S/D epi stacks of the X and Y1 views. From left to right, the S/D epi stacks represent the S/D epis at device regions 252-1, 252-2, 252-3, 252-4, and include a deep backside contact 208-D, shallow backside contact 208-S, deep backside contact 208-D, and a deep frontside contact 208-DF. The deep frontside contact 208-DF shorts the bottom S/D epi 214-B and the top S/D epi 214-T together.

Further, between the S/D epi stacks at device regions 252-1 and 252-2, the Y2 view includes a pillar of a first dielectric material 217-1 and a second dielectric material 217-2, STI layer 218, and backside ILD layer 216. Additionally, between the S/D epi stacks at device regions 252-2 and 252-3, the Y2 view includes a deep via 210 in contact with the BEOL 204 and the shallow backside contact 208-S. Additionally, on either side of the deep via 210, the backside ILD layer 216 isolates the deep via 210 from the neighboring S/D epis 214. The backside ILD layer 216 is also in contact with STI layer 218. In this way, the example semiconductor device 200 provides a conductive path between signal wiring in the BEOL 204 with the bottom S/D epi for a bottom FET in a stacked FET device.

Further, between the S/D epi stacks at device regions 252-3 and 252-4, the Y2 view includes a deep via 210 in contact with the contact 208-A at the top of the S/D epi stack, and the BSPR 222-VDD. Additionally, on either side of the deep via 210, the backside ILD layer 216 isolates the deep via 210 from the neighboring S/D epi stacks. In this way, the deep via 210 provides a conductive path from the top S/D epi 214T to the BSPR 222-VDD.

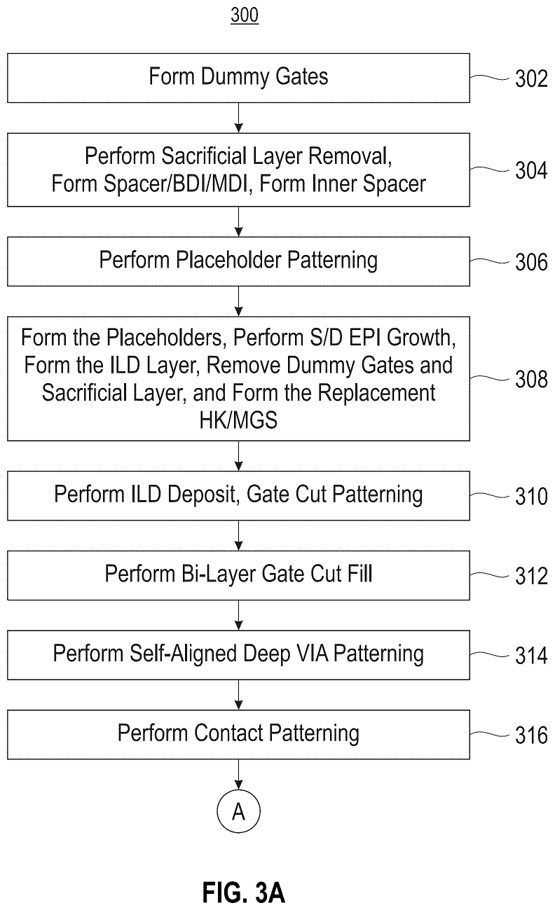

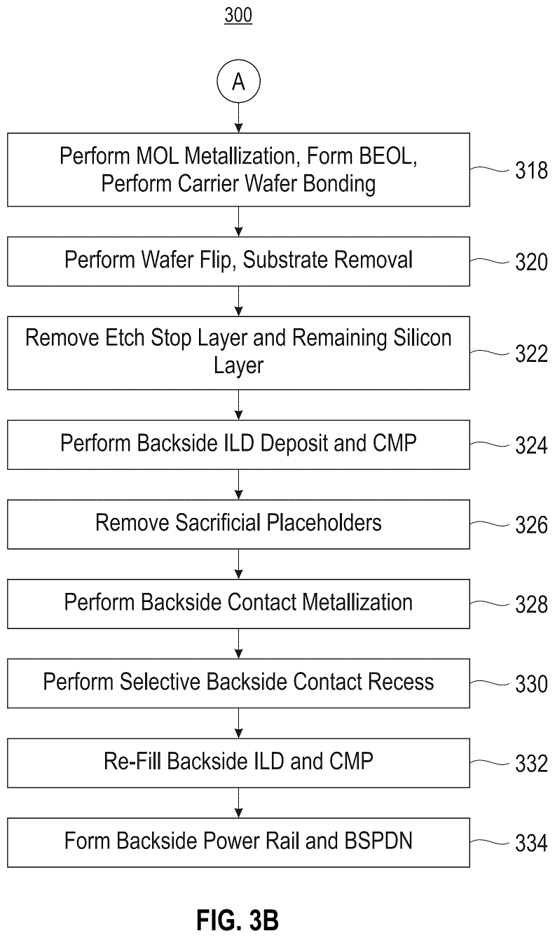

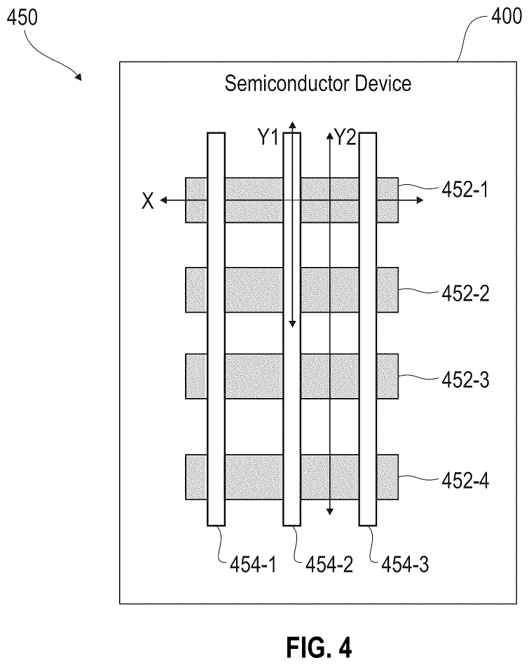

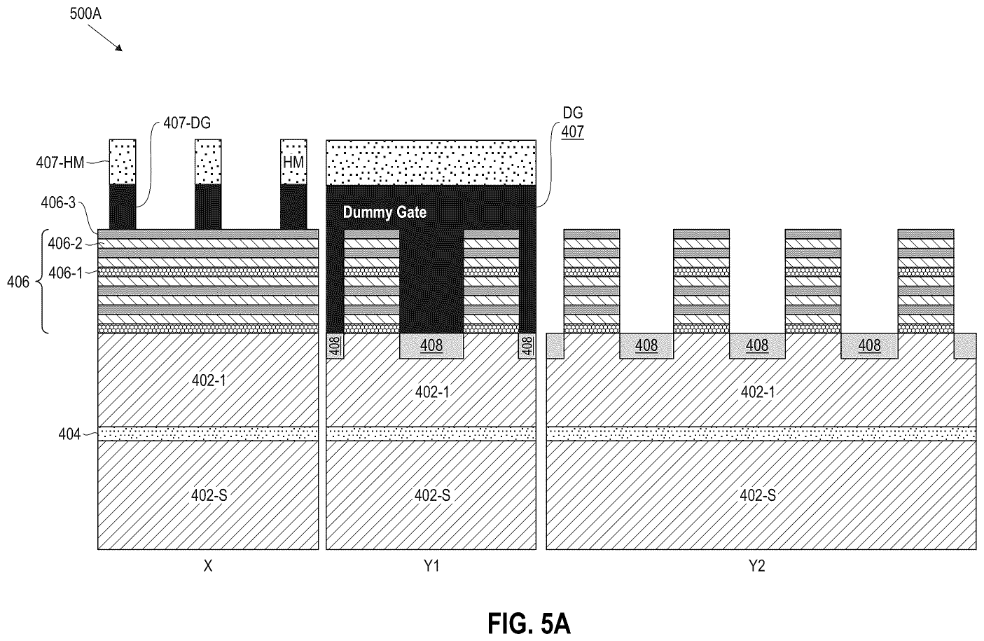

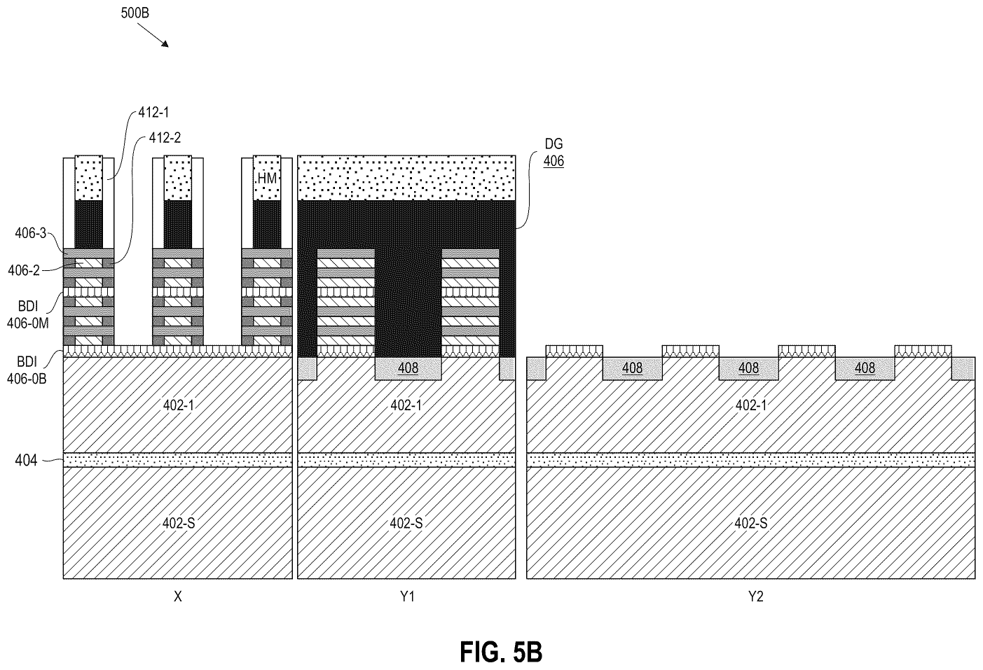

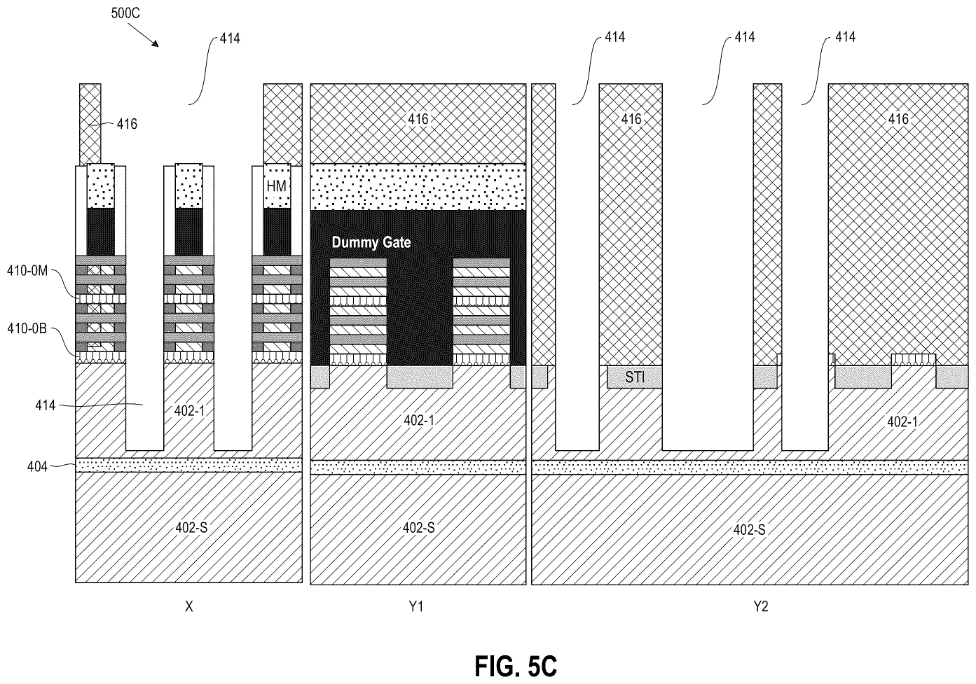

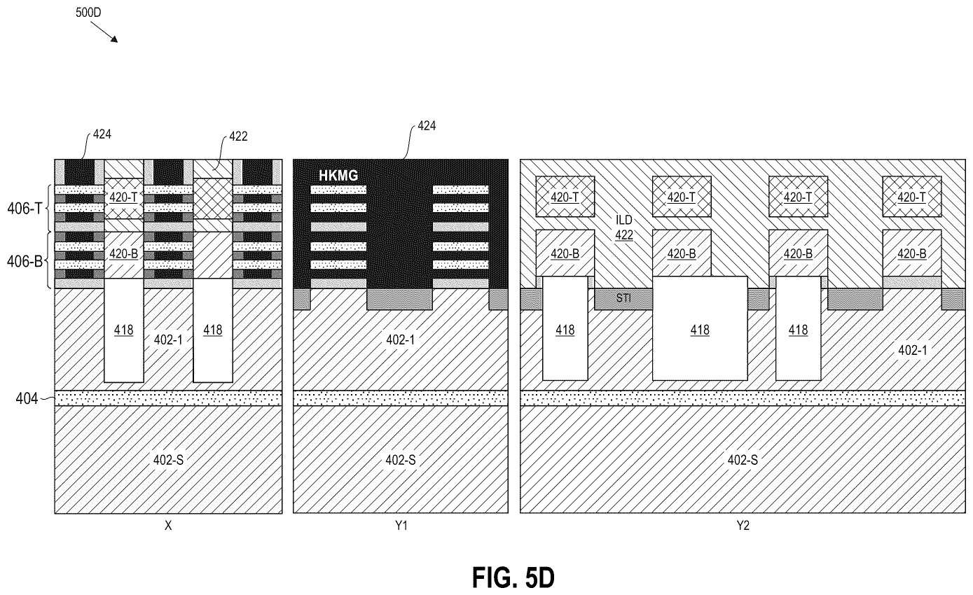

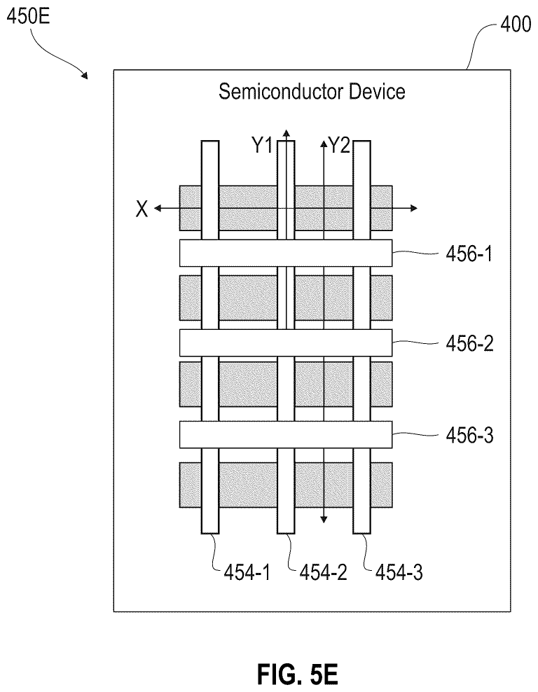

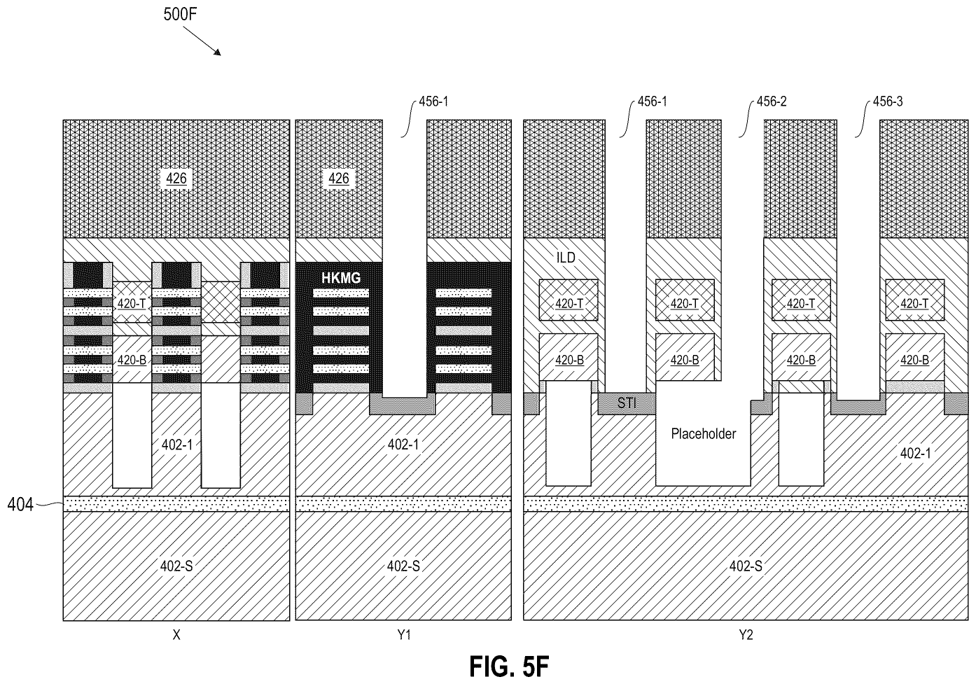

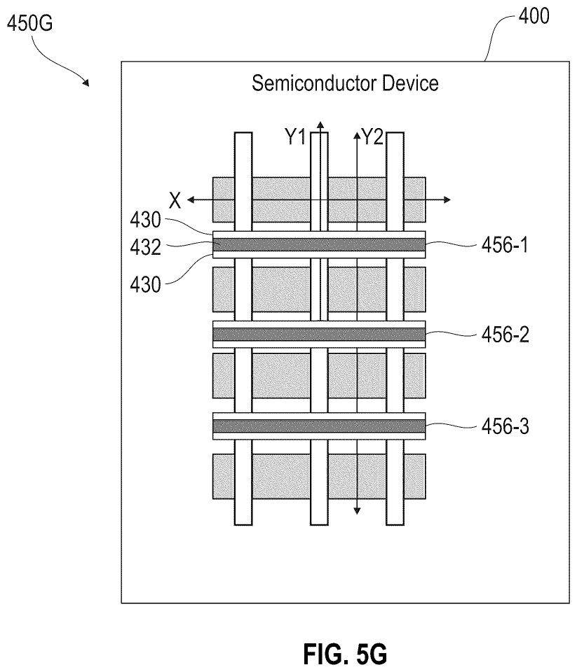

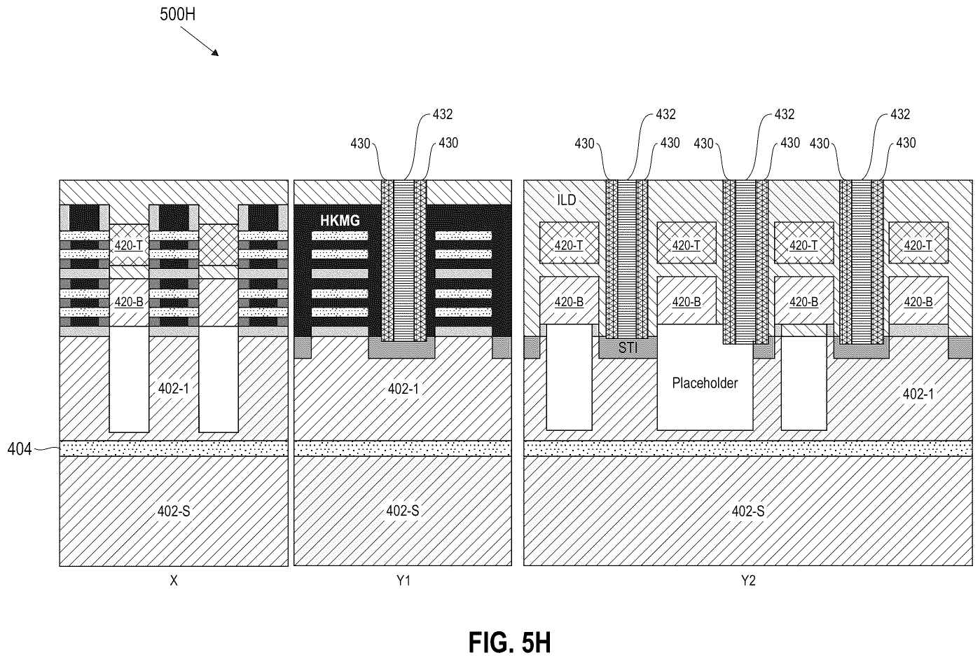

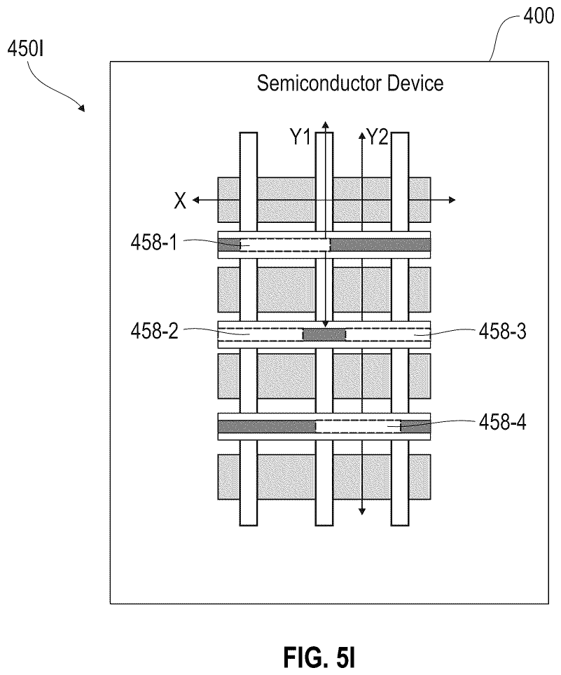

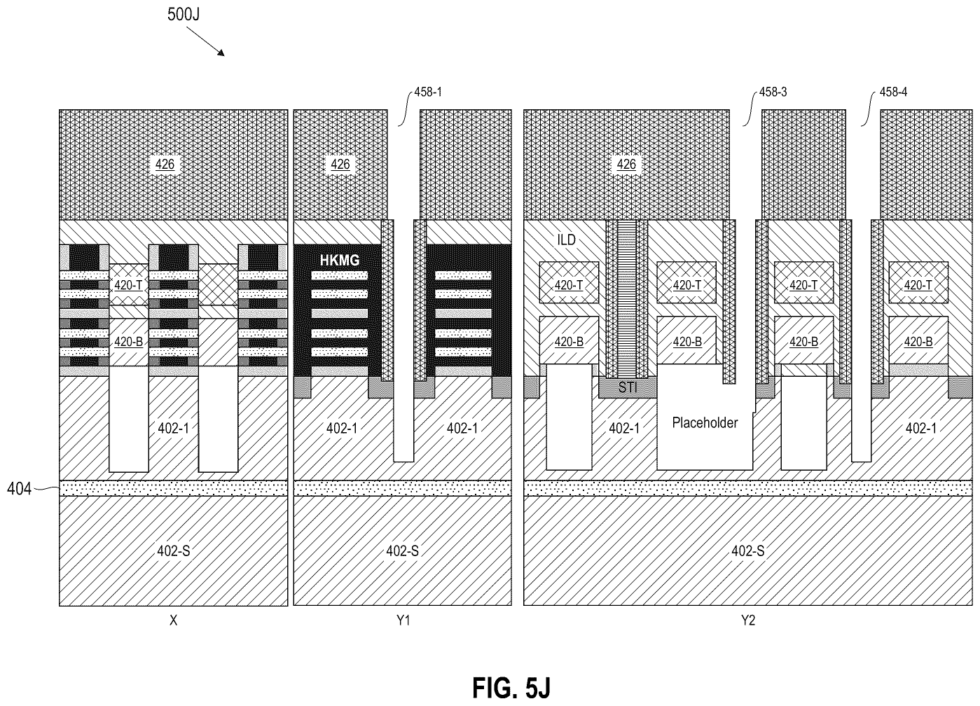

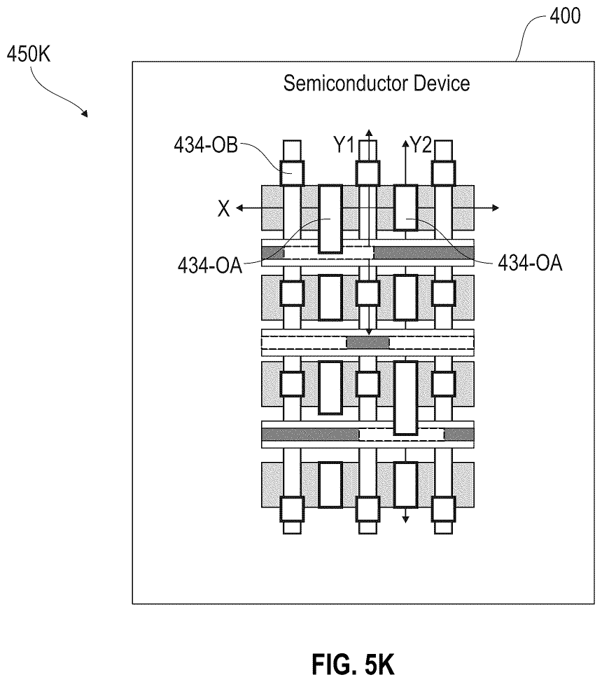

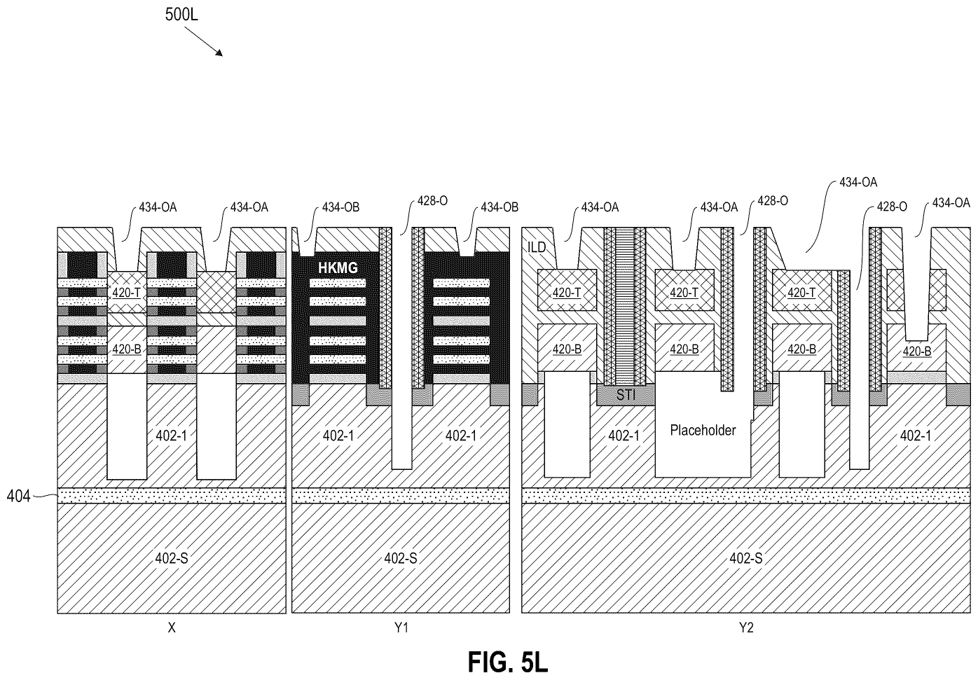

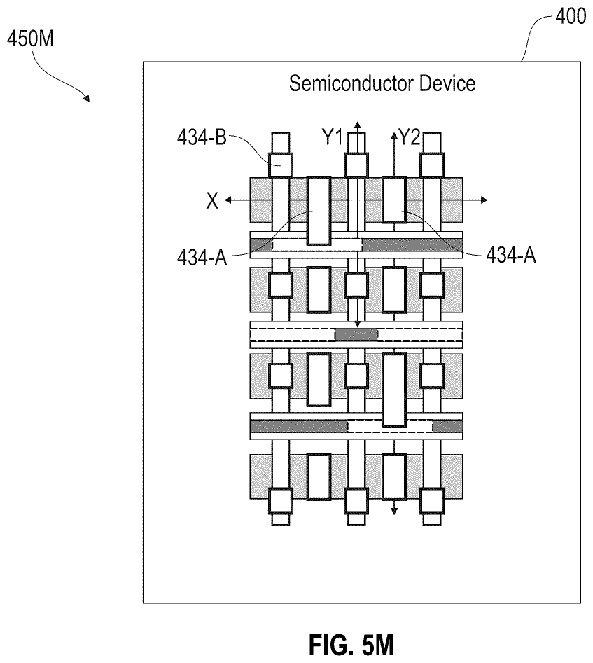

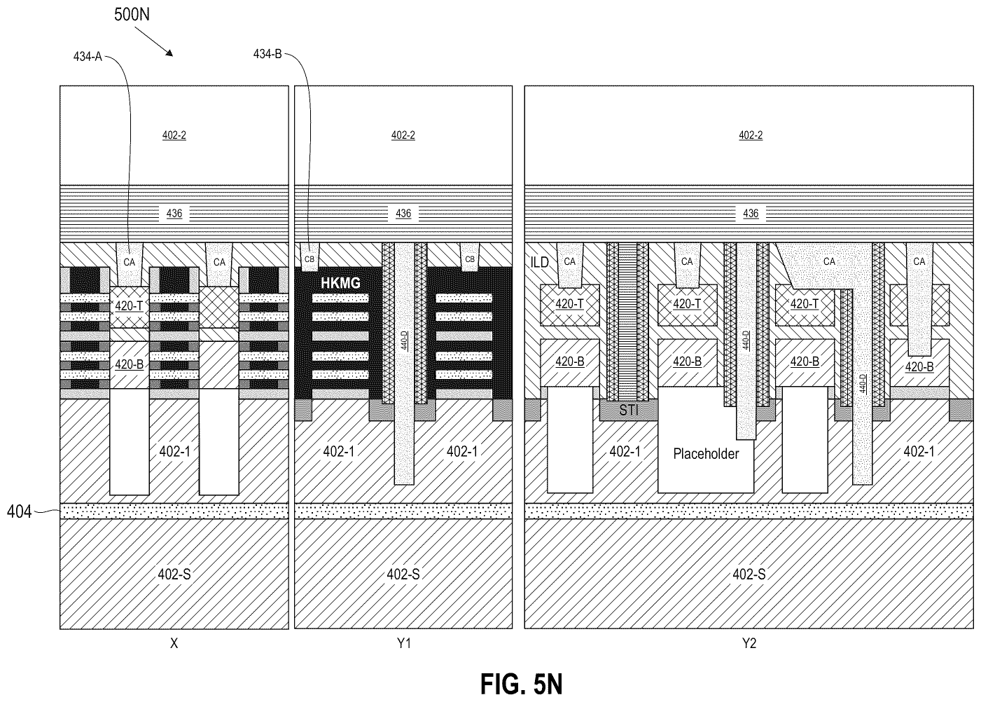

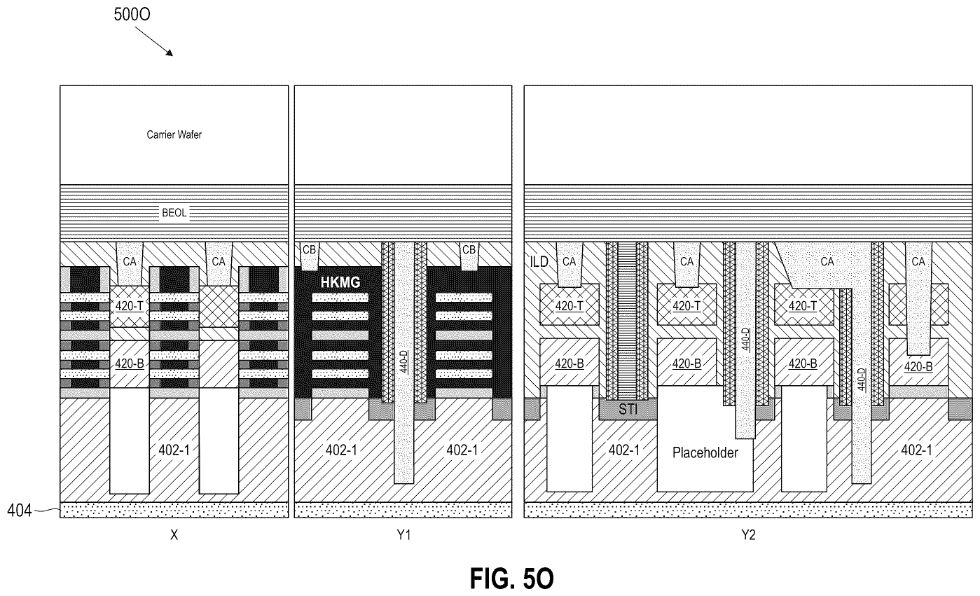

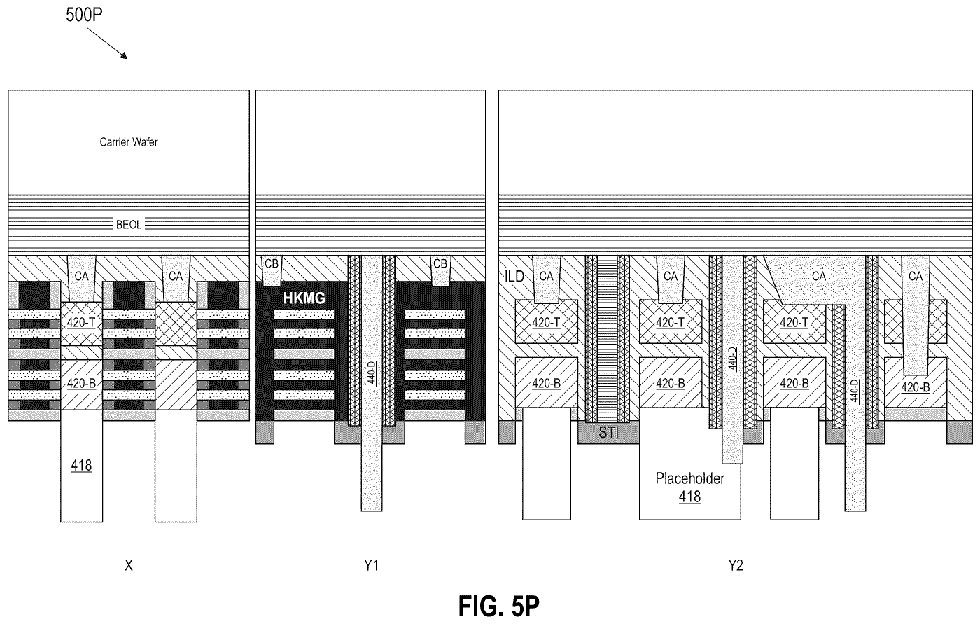

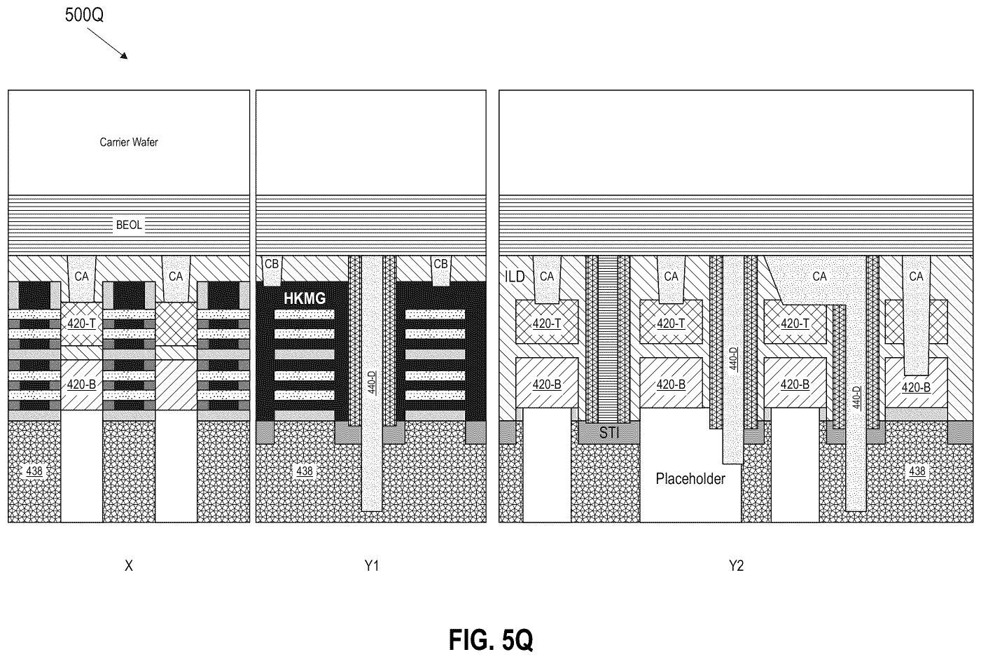

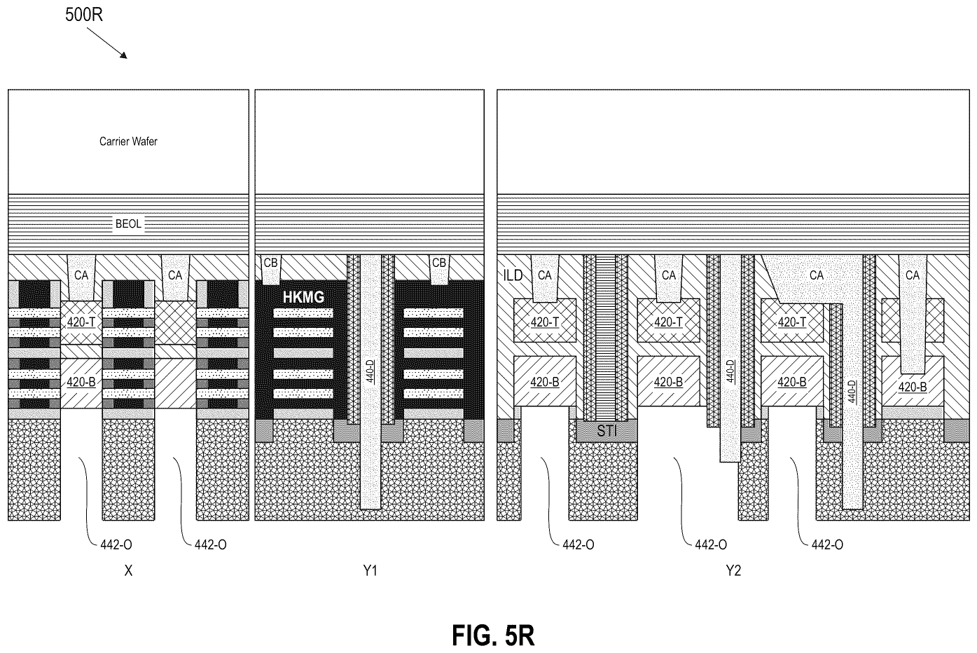

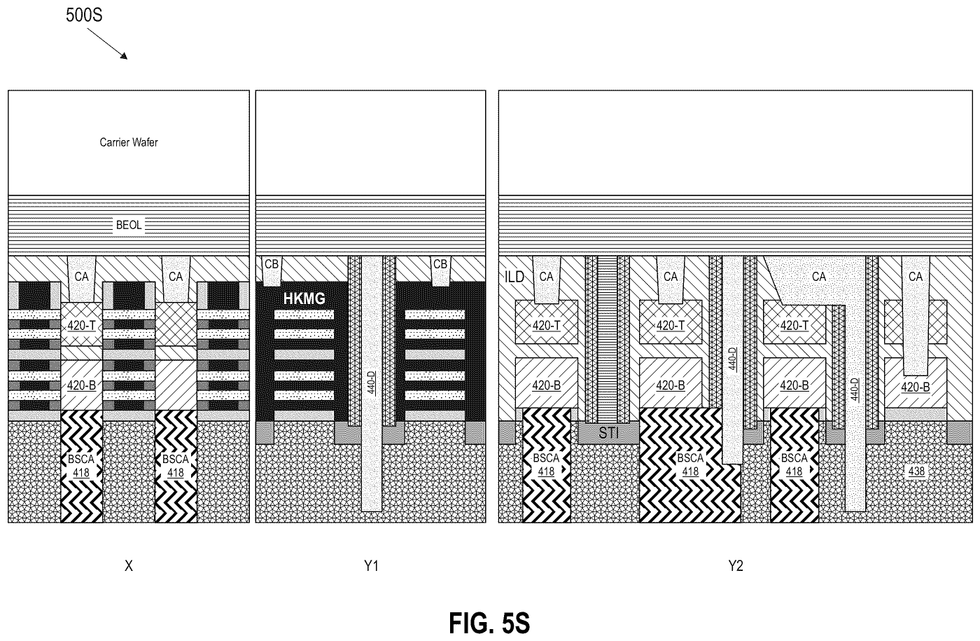

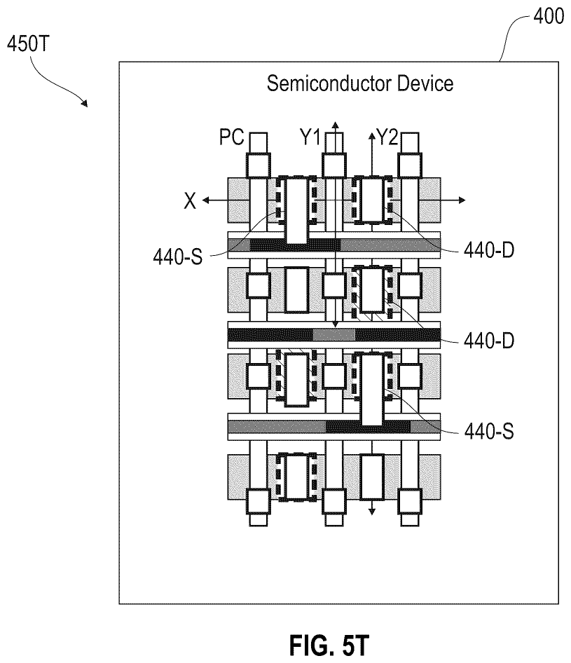

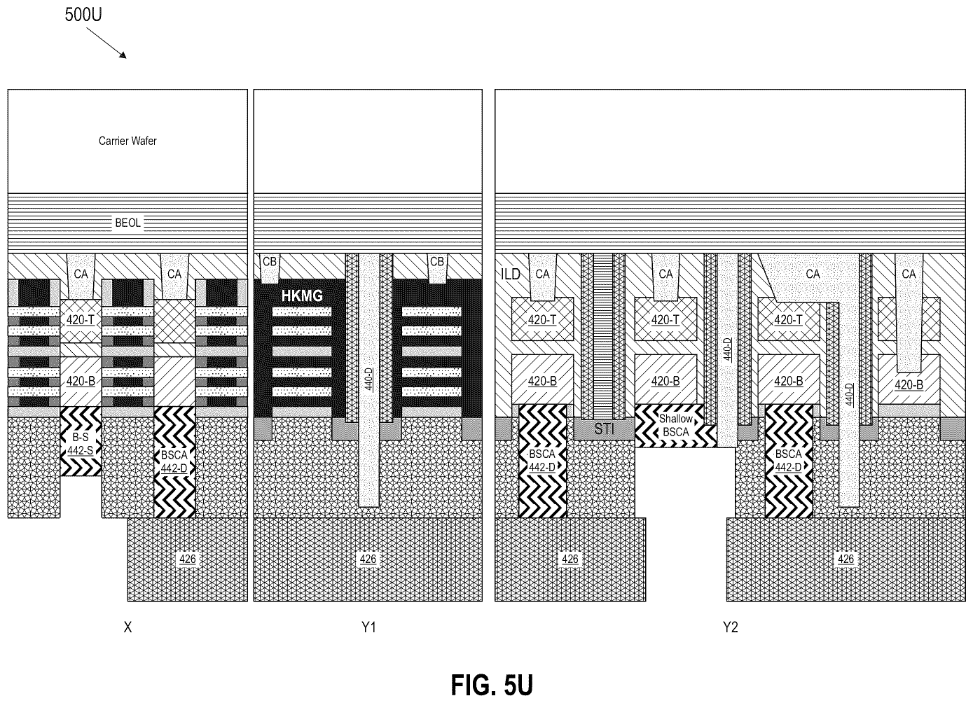

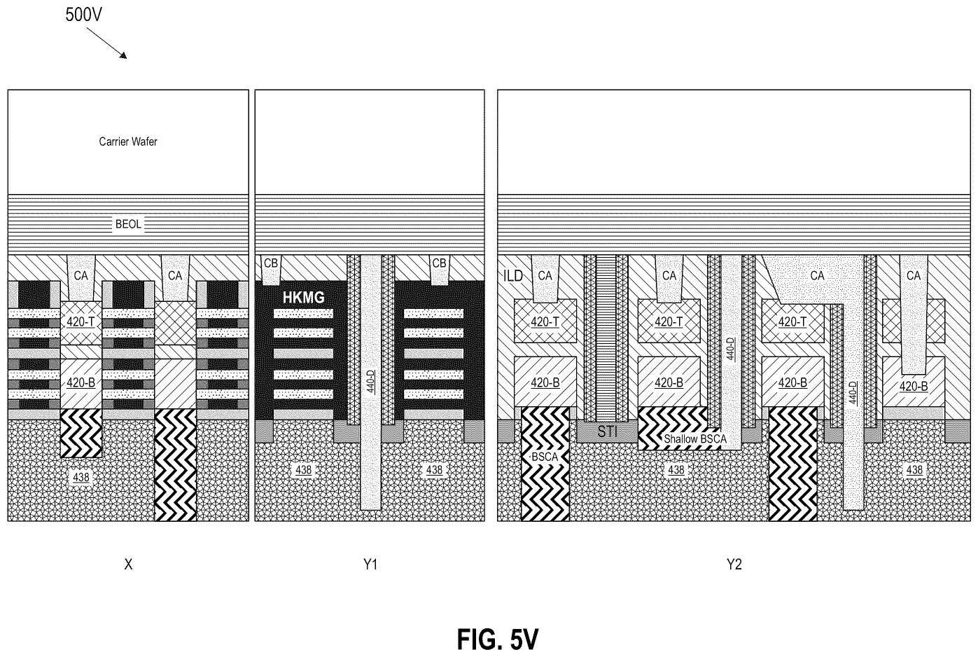

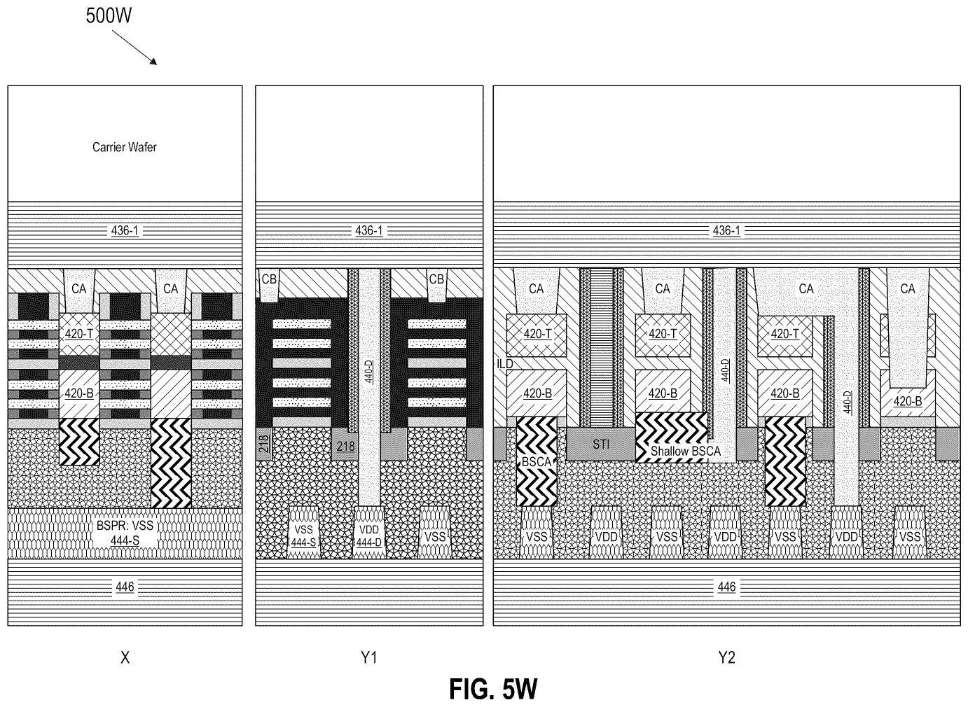

FIG. 3 (encompassing FIGS. 3A and 3B) is a process flow chart of a method 300 for fabricating a semiconductor device, in accordance with some embodiments of the present disclosure. In some embodiments, an example semiconductor device fabrication manager, such as the semiconductor device fabrication manager 150 described with respect to FIG. 1, can perform the method 300. In this method, the semiconductor device fabrication manager 150 can fabricate a semiconductor device, such as the semiconductor device 200, described with respect to FIG. 2. For clarity, the method 300 is described with respect to FIGS. 4 and 5A through 5 W, which provide views of an example semiconductor device being fabricated after each operation of the method 300. Further, the views represented in 4 and FIGS. 5A-5W are merely examples of views that method 300 may produce. However, some practices of the method 300 may produce other views.

At operation 302, semiconductor device fabrication manager 150 can direct a fabrication tool to form dummy gates. Forming dummy gates can involve depositing sacrificial layers that serve as placeholders for gates. More specifically, the semiconductor device fabrication manager 150 can direct a fabrication tool to form a patterned nanosheet stack over an isolation layer. Nanosheet patterning can involve forming a patterned nanosheet stack over an underlying layer. More specifically, the fabrication tool may deposit alternate nanosheet layers of sacrificial nanosheet layers with nanosheet channel layers. The sacrificial nanosheet layers may be composed of silicon germanium (e.g., SiGe). Additionally, the channel layers may be composed of Si. Further, forming the dummy gate can involve depositing material forming the dummy gate and gate hardmask over the patterned nanosheet stack. For clarity, operation 302 is described with respect to FIGS. 4 and 5A.

FIG. 4 is a block diagram of an overhead view 450 of the example semiconductor device 400 during fabrication, in accordance with some embodiments of the present disclosure. In the overhead view 450, the example semiconductor device 400 includes device regions 452-1, 452-2, 452-3, 452-4 (collectively referred to as device regions 452) and gate regions 454-1, 454-2, 454-3 (collectively referred to as gate regions 454). The device regions 452 represent the locations of the channels and S/D epis to be fabricated. Similarly, the gate regions 454 indicate the locations of the gates to be fabricated, specifically, at the intersecting device region 452 and gate region 454. The overhead view 450 is similar to the overhead view 250A described with respect to FIG. 2A. Accordingly, the overhead view 450 includes X, Y1, and Y2 cut lines, which corresponding to cross-sectional views, described below, with respect to FIGS. 5A-5D.

As described below, FIGS. 5A-5W include fabrication states of an example semiconductor device during fabrication. Notably, these figures include a number of elements, each of which is labeled for discussion. However, due to the number of elements, including reference numbers for every element may make the figure crowded and confusing. As such, the following steps are taken to limit the re-use of reference numbers in the figures. For example, these figures include multiple views of the same apparatus. As such, the views share some of the same elements. Thus, to limit the reference numbers, a reference number is only placed on the left most view of the element. As such, like elements (without reference numbers) are indicated by: the same vertical position (as shown), and the same hash pattern (or lack thereof). Further, when an element is added to a figure, the element has a reference number. However, subsequent figures may not include the reference number even though the element remains. For example, elements introduced, and thus, labeled in FIG. 5A, may not be labeled in FIG. 5B. While these steps are useful for reducing clutter in the figures, in the interest of clarity of description, there are some exceptions to the labeling as described above.

FIG. 5A is an example fabrication state 500A of the example semiconductor device 400 during fabrication, according to some embodiments of the present disclosure. The example fabrication state 500A may represent the state of the semiconductor device after operation 302. The example fabrication state 500A includes X, Y1, and Y2 views, which correspond to the X, Y1, and Y2 cutlines described with respect to FIG. 4. Similar to example semiconductor device 200, described with respect to FIG. 2B, the views of example fabrication state 500A share features that are similar across the views. For example, the X, Y1, and Y2 views all include a substrate 402-S (e.g., silicon (Si)), etch stop layer 404, silicon layer 402-1, and patterned nanosheet stack 406. Additionally, the nanosheet stack 406 includes sacrificial layers 406-1, 406-2, which may be composed of SiGe60 and SiGe30, respectively. Further, the nanosheet stack 406 includes nanosheet channels 406-3, which may be composed of a semiconductor material, such as Si.

Further, the X and Y1 views both include a dummy gate 407-DG, and gate hardmask 407-HM. The dummy gate can serve as a placeholder for the actual gate, fabricated at a different fabrication state. The gate hardmask 407-HM may be a cap that facilitates nanosheet stack patterning. The dummy gates 407-DG of the X view can represent the locations of the gate regions 454-1, 454-2, 454-3 (from left to right, as shown), described with respect to FIG. 4.

Additionally, the Y1 view includes two nanosheet stacks 406, representing device regions 452-1, and 452-2 along cut line Y1. Further, the Y1 view includes STI layer 408, in trenches between, and on either side of, the two nanosheet stacks 406. The STI layer 408 can be similar to the STI layer 218, described with respect to FIG. 2.

Further, the Y2 view includes four nanosheet stacks 406, representing device regions 452-1, 452-2, 452-3, 452-4 along cut line Y2. Similar to the Y1 view, the Y2 view includes the STI layer 408 between, and on either side of, the nanosheet stacks 406. In this way, the example fabrication state 500A can represent a state of the semiconductor device being fabricated after performing operation 302.

Referring back to FIG. 3A, at operation 304, the semiconductor device fabrication manager 150 can direct a fabrication tool to perform the sacrificial layers removal; form spacers, BDI, MDI, and inner spacers. The fabrication tool removes sacrificial layers 406-1, which may be composed of an SiGe material, such as SiGe60. Removing the SiGe60 layers can involve etching the sacrificial layers 406-1, selective to the Si nanosheet channels 406-3, and other surrounding materials.

Further, forming the spacers can involve a conformal dielectric deposition and an anisotropic reactive-ion etching (RIE) to remove the spacer material from horizontal surfaces. The spacers may be a dielectric material (e.g., SiN, SiBCN, SiOCN, SiOC, and the like). Additionally, forming the BDI involves depositing a dielectric material in a region previously occupied by a sacrificial layer removed from the bottom of the nanosheet stack 406. Similarly, forming the MDI involves depositing a dielectric material in a region previously occupied by a sacrificial layer removed from the middle of the nanosheet stack 406.

Additionally, forming the inner spacers can involve performing a nanosheet recess, SiGe indentation, and inner spacer formation. More specifically, performing nanosheet recess can involve etching back the nanosheet stacks (e.g., sacrificial layer 406-2 and nanosheet channels 406-3). Additionally, the SiGe indentation can involve a mechanical process to remove portions of the sacrificial layer 406-2 to provide enough room to deposit material to form the inner spacers 412-2. Further, inner spacer formation can involve depositing dielectric material in the spaces created by the SiGe indentation. For clarity, operation 304 is described with respect to FIG. 5B.

FIG. 5B is an example fabrication state 500B of the example semiconductor device 400 during fabrication, according to some embodiments of the present disclosure. In comparison to example fabrication state 500A, the X view of example fabrication state 500B, includes two trenches between the dummy gates 407-DG, thus forming three nanosheet stacks 406. Additionally, the X view includes BDI layer 406-0B and MDI layer 406-0M in the regions previously occupied by the removed sacrificial layers 406-1. Further, the X view includes spacers 412-1 on either side of the dummy gates 407-DG and gate hardmasks 407-HM. Similar to the X view, the Y1 view includes BDI layer 406-0B and MDI layer 406-0M in the regions previously occupied by the removed sacrificial layers 406-1. In this way, the example fabrication state 500B can represent a state of the semiconductor device being fabricated after performing operation 304.

Referring back to FIG. 3A, at operation 306, the semiconductor device fabrication manager 150 can direct a fabrication tool to perform placeholder patterning. Performing placeholder patterning can involve depositing the mask material (such as an organic planarization layer (OPL)) followed by conventional lithographic patterning. Additionally, placeholder patterning involves creating trenches that pass through the OPL and into the silicon layer 402-1 and STI layer 408. For clarity, operation 306 is described with respect to FIG. 5C.

FIG. 5C is an example fabrication state 500C of the example semiconductor device 400 during fabrication, according to some embodiments of the present disclosure. In comparison to example fabrication state 500B, the X view of example fabrication state 500C additionally includes trenches 414 and OPL 416. As stated previously, the trenches pass through the OPL 416 and into the silicon layer 402-1. In these ways, the example fabrication state 500C can represent a state of the semiconductor device being fabricated after performing operation 306.

Referring back to FIG. 3A, at operation 308, the semiconductor device fabrication manager 150 can direct a fabrication tool to form the placeholders, perform S/D epi growth, form the ILD layer, remove dummy gates and sacrificial layer, and form the replacement HK/MGs. Forming the placeholder involves depositing a sacrificial material in the trenches 414 and recess it to be level with the BDI layer 406-0B, or forming sacrificial placeholder 418 through a bottom-up deposition process, such as selective epitaxy growth. Further, performing S/D epi growth involves growing semiconductor S/D epitaxy from exposed semiconductor surfaces (e.g., the nanosheet channels 406-3). Additionally, forming the ILD layer involves performing an interlayer dielectric (ILD) deposition on the STI layer 408 and grown S/D epis. Further, forming the ILD layer includes performing a chemical mechanical planarization (CMP), which removes material (e.g., material of the gate hardmask 407-HM, ILD layer 422) to form a planar surface. For dummy gate removal, the fabrication tool may remove the dummy gates 407-DG selective to the surrounding materials (e.g., ILD). Further, removing the sacrificial layer 406-2 involves a SiGe release. For the SiGe release, the fabrication tool may etch the sacrificial layers 406-2 (e.g., SiGe30) selective to the Si of the nanosheet channels 406-3 and other surrounding materials. Additionally, forming the replacement gates involves depositing high-k metal gate material in the spaces created by removing the dummy gates 407-DG and sacrificial layers 406-2. For clarity, operation 308 is described with respect to FIG. 5D.

FIG. 5D is an example fabrication state 500D of the example semiconductor device 400 during fabrication, according to some embodiments of the present disclosure. In comparison to example fabrication state 500C, the X and Y1 views of example fabrication state 500D no longer include the dummy gate 407-DG, gate hardmask 407-HM, and sacrificial layer 406-2. Additionally, in comparison to example fabrication state 500C, the X view includes three gate stacks and two intervening S/D epi stacks. The gate stacks include bottom FET 406-B, which includes (from bottom to top) BDI layer 406-0B, inner spacers 412-2, and alternating layers of HK/MG 424 and nanosheet channels 406-3. The top FET 406-T includes the MDI layer 406-0M, inner spacers 412-2, and alternating layers of HK/MG 424 and nanosheet channels 406-3. Additionally, the S/D epi stacks include (from bottom to top) sacrificial placeholders 418, bottom S/D epi 420-B, ILD layer 422, top S/D epi 420-T, and ILD layer 422. In contrast to the three gate stacks of the X view, the Y1 view includes two gate stacks. These gate stacks include the elements of a top FET 406-T and bottom FET 406-B. The Y2 view includes four S/D epi stacks, which are similar to the S/D epi stacks described with respect to the X view. However, the second S/D epi stack from the left includes a placeholder that extends beyond the right edge of the overlaying S/D epis. In this way, the sacrificial placeholder 418 makes it possible to create a via that reaches a contact to be created in place of the sacrificial placeholder 418. Additionally, the right-most S/D epi stack does not include a sacrificial placeholder 418. In this way, FIG. 5D can represent a state of the semiconductor device being fabricated after operation 308.

Referring back to FIG. 3A, at operation 310, the semiconductor device fabrication manager 150 can direct a fabrication tool to perform ILD deposit and gate cut patterning. Performing the ILD deposit involves depositing ILD material on the semiconductor device being fabricated. Additionally, performing gate cut patterning involves performing a sacrificial material overfill on the deposited ILD, and removing the sacrificial material and the deposited ILD to create gate cuts down to the STI layer 408, and between the device regions 452. For clarity, operation 310 is further described with respect to FIGS. 5E and 5F.

FIG. 5E is a block diagram of an overhead view 450E of the example semiconductor device 400 during fabrication, in accordance with some embodiments of the present disclosure. The overhead view 450E is similar to the overhead view 450, and additionally includes gate cuts 456-1, 456-2, 456-3 (collectively referred to as gate cuts 456), between the device regions 454.

FIG. 5F is a block diagram of an example fabrication state 500F of the example semiconductor device 400 during fabrication, in accordance with some embodiments of the present disclosure. In comparison to example fabrication state 500D, the X, Y1, and Y2 views of example fabrication state 500F additionally include additional ILD in the ILD layer 422, and the OPL 426. Further, the Y1 view additionally includes gate cut 456-1. Similarly, the Y2 view additionally includes gate cuts 456-1, 456-2, 456-3. In this way, FIG. 5F can represent a state of the semiconductor device being fabricated after operation 310.

Referring back to FIG. 3A, at operation 312, the semiconductor device fabrication manager 150 can direct a fabrication tool to perform a bi-layer gate cut fill. Performing the bi-layer gate cut fill involves removing the OPL 426. Additionally, performing the bi-layer gate cut fill includes lining the gate cuts 456 with a first dielectric material, and filling the lined gate cuts with a second dielectric material, different from the first dielectric material. For example, the first dielectric material may be silicon nitride (SiN), and the second dielectric material may be silicon oxide (SiO₂). For clarity, operation 312 is further described with respect to FIGS. 5G, 5H.

FIG. 5G is a block diagram of an overhead view 450G of the example semiconductor device 400 during fabrication, in accordance with some embodiments of the present disclosure. The overhead view 450G is similar to the overhead view 450E, and the gate cuts 456 additionally include the first dielectric material 430, and the second dielectric material 432.

FIG. 5H is a block diagram of an example fabrication state 500H of the example semiconductor device 400 during fabrication, in accordance with some embodiments of the present disclosure. In comparison to example fabrication state 500F, the X, Y1, and Y2 views of example fabrication state 500H no longer include the OPL 426. Additionally, the Y1 and Y2 views include the first dielectric material 430 lining the gate cuts 456, and the second dielectric filling the gate cuts 456. In this way, FIG. 5H can represent the semiconductor device being fabricated after operation 312.

Referring back to FIG. 3A, at operation 314, the semiconductor device fabrication manager 150 can direct a fabrication tool to perform self-aligned deep via patterning. Performing self-aligned deep via patterning involves performing a sacrificial material overfill and creating deep trenches through the OPL 426, second dielectric material 432, STI layer 408, and either: into the silicon layer 402-1, or to expose a sacrificial placeholder 418. For clarity, operation 314 is further described with respect to FIGS. 5I, 5J.

FIG. 51 is a block diagram of an overhead view 450I of the example semiconductor device 400 during fabrication, in accordance with some embodiments of the present disclosure. The overhead view 450I is similar to the overhead view 450G, and additionally includes deep trenches 458-1, 458-2, 458-3, 458-4 (collectively referred to as deep trenches 458).

FIG. 5J is a block diagram of an example fabrication state 500J of the example semiconductor device 400 during fabrication, in accordance with some embodiments of the present disclosure. In comparison to example fabrication state 500H, the X, Y1, and Y2 views of example fabrication state 500J include the OPL 426 on top of the ILD layer 422. Additionally, the Y1 view includes the deep trench 458-1 located between two gate stacks. Further, the Y2 view of example fabrication state 500G includes deep trench 458-3 (which exposes the sacrificial placeholder 418) located between two gate stacks, and deep trench 458-4 (which passes down to the silicon layer 402-1) located between to S/D epi stacks. In this way, FIG. 5J can represent the semiconductor device being fabricated after operation 314.

Referring back to FIG. 3A, at operation 316, the semiconductor device fabrication manager 150 can direct a fabrication tool to perform contact patterning. Performing contact patterning involves removing the OPL 426 and material from the ILD layer 422 to expose the top S/D epis 420-T, HK/MGs 424, a bottom S/D epi 420-B in device region 452-3, and creating openings for deep vias. For clarity, operation 316 is further described with respect to FIGS. 5K, 5L.

FIG. 5K is a block diagram of an overhead view 500K of the example semiconductor device 400 during fabrication, in accordance with some embodiments of the present disclosure. The overhead view 450K is similar to the overhead view 450I, and additionally includes frontside contact openings 434-OA, 434-0B (also referred to individually as S/D epi openings 434-OA, and gate openings 434-0B).

FIG. 5L is a block diagram of an example fabrication state 500L of the example semiconductor device 400 during fabrication, in accordance with some embodiments of the present disclosure. In comparison to example fabrication state 500J, the X, Y1, and Y2 views of example fabrication state 500L no longer include the OPL 426. Additionally, the X view includes S/D contact openings 434-OA to the top S/D epis 420-T. The Y1 view additionally includes gate openings 434-0B to the HK/MGs 424 of the top FETs 406-T. Additionally, the Y2 view includes three S/D openings 434-OA to the tops of the respective top S/D epis 420-T, and a fourth S/D opening 434-OA to a side of both a top S/D epi 420-T and bottom S/D epi 420-B in device region 452-4. The Y2 view also includes three deep via openings 428-DO: one located near the middle of the Y2 view; the second being located near the middle of the Y2 view, and exposing the sacrificial placeholder 418; and the third being located to the right of the second deep via in the Y2 view. In this way, FIG. 5L can represent the semiconductor device being fabricated after operation 316.

Referring back to FIG. 3A, the operation 316 shows a flow to a placeholder A. The placeholder A does not represent an operation of the method, but serves to connect the operations described in FIG. 3A with the other operations of method 300, which are described in greater detail with respect to FIG. 3B.

FIG. 3B is a process flow chart of operations 318 through 334 of the method 300, in accordance with some embodiments of the present disclosure. For clarity, these operations are described with respect to FIGS. 5M through 5W.

The process flow chart of FIG. 3B shows a flow from placeholder A to operation 318. As stated previously, the placeholder A does not represent an operation of the method 300, but serves to connect the operations 302-316 described in FIG. 3A with operations 318-334 described below.

At operation 318, the semiconductor device fabrication manager 150 can direct a fabrication tool to perform middle of line (MOL) metallization, form the BEOL, and perform carrier wafer bonding. Performing MOL metallization includes filling the frontside contact openings 434-OA, 434-0B with conductive metal to create frontside contacts. Additionally, performing BEOL interconnect formation can involve fabricating the elements of the BEOL interconnect 436, such as, multiple layers of Cu based metal lines and vias. Further, carrier wafer bonding can involve bonding the carrier wafer 402-2 to the BEOL interconnect 436. For clarity, operation 318 is further described with respect to FIGS. 5M, 5N.

FIG. 5M is a block diagram of an overhead view 450M of the example semiconductor device 400 during fabrication, in accordance with some embodiments of the present disclosure. The overhead view 450M is similar to the overhead view 450K, and additionally includes frontside contacts 434-A, 434-B, in place of the respective frontside contact openings 434-OA, 434-0B. For clarity, not all frontside contacts are labeled. Rather, the boxes indicating frontside contacts 434-A, 434-B also represent similar contacts in similar sized boxes. Herein, the frontside contacts 434-A, 434-B are individually referred to as S/D contacts 434-A and gate contacts 434-B.

FIG. 5N is a block diagram of an example fabrication state 500N of the example semiconductor device 400 during fabrication, in accordance with some embodiments of the present disclosure. In comparison to example fabrication state 500L, the X, Y1, and Y2 views of example fabrication state 500N additionally include a carrier wafer 402-2 and BEOL interconnect 436. Further, the X view includes S/D contacts 434-A on the top S/D epis 420-T. The Y1 view additionally includes gate contacts 434-B to the HK/MGs 424. Further, the Y1 view includes a deep via 440-D into the silicon layer 402-1. The Y2 view additionally includes three S/D contacts 434-A to the top of the respective top S/D epis 420-T, and a fourth S/D contact 434-A to a side of both a top S/D epi 420-T and bottom S/D epi 420-B. Additionally, the Y2 view includes two deep vias 440-D, between the device regions 452-2, 452-3, and extending down to the sacrificial placeholder 418. The second deep via 440-D extends down to the silicon layer 402-1. In this way, FIG. 5N can represent the semiconductor device being fabricated after operation 318.

Referring back to FIG. 3A, at operation 320, the semiconductor device fabrication manager 150 can direct a fabrication tool to perform a wafer flip and substrate removal. Performing the wafer flip can involve reversing the vertical orientation of the semiconductor device being fabricated. The wafer flip can thus expose the substrate 402-S for removal. Performing the substrate removal involves an etching process that removes the substrate material from the exposed surface to the etch stop layer 404. For clarity, operation 320 is further described with respect to FIG. 5O.

FIG. 5O is a block diagram of an example fabrication state 5000 of the example semiconductor device 400 during fabrication, in accordance with some embodiments of the present disclosure. In comparison to example fabrication state 500N, the X, Y1, and Y2 views of example fabrication state 5000 no longer include the substrate 402-S. In this way, FIG. 5O can represent the semiconductor device being fabricated after operation 320.

Referring back to FIG. 3A, at operation 322, the semiconductor device fabrication manager 150 can direct a fabrication tool to remove the etch stop layer 404 and remaining silicon layer 402-1. Removing the etch stop layer 404 and silicon layer 402-1 exposes the underlying sacrificial placeholders, BDI layer 406-0B, STI layer 408, and deep vias 440-D. For clarity, operation 322 is further described with respect to FIG. 5P.

FIG. 5P is a block diagram of an example fabrication state 500P of the example semiconductor device 400 during fabrication, in accordance with some embodiments of the present disclosure. In comparison to example fabrication state 5000, the X, Y1, and Y2 views of example fabrication state 500P no longer include the silicon layer 402-1 and etch stop layer 404. In the X1 view, removing these layers exposes the sacrificial placeholders 418 beneath the bottom S/D epis 420-B. In the Y1 view, removing these layers exposes the STI layer 408, BDI layer 406-0B, and deep via 440-D. In the Y2 view, removing these layers exposes three sacrificial placeholders 418, the right-most deep via 440-D, and right-most BDI layer 406-0B. In this way, FIG. 5P can represent the semiconductor device being fabricated after operation 322.

Referring back to FIG. 3A, at operation 324, the semiconductor device fabrication manager 150 can direct a fabrication tool to perform backside ILD deposit and CMP. Performing backside ILD deposit involves depositing ILD material on the surfaces exposed by removing the silicon and etch stop layers. Performing CMP involves creating a planar surface on the deposited ILD. For clarity, operation 324 is further described with respect to FIG. 5Q.

FIG. 5Q is a block diagram of an example fabrication state 500Q of the example semiconductor device 400 during fabrication, in accordance with some embodiments of the present disclosure. In comparison to example fabrication state 500P, the X, Y1, and Y2 views of example fabrication state 500Q additionally include the ILD layer 438. In this way, FIG. 5Q can represent the semiconductor device being fabricated after operation 324.

Referring back to FIG. 3A, at operation 326, the semiconductor device fabrication manager 150 can direct a fabrication tool to remove sacrificial placeholders 418. Removing the sacrificial placeholders 418 can involve selective dry etch or wet etch processes. For clarity, operation 326 is further described with respect to FIG. 5R.

FIG. 5R is a block diagram of an example fabrication state 500R of the example semiconductor device 400 during fabrication, in accordance with some embodiments of the present disclosure. In comparison to example fabrication state 500Q, the X, Y1, and Y2 views no longer include the sacrificial placeholders 418. The remaining regions leave backside contact openings 442-O. In this way, FIG. 5R can represent the semiconductor device being fabricated after operation 326.

Referring back to FIG. 3A, at operation 328, the semiconductor device fabrication manager 150 can direct a fabrication tool to perform backside contact metallization. Backside contact metallization can include depositing conductive metal material in the backside contact openings 442-O. In this way, some embodiments of the present disclosure can provide backside contacts wiring: the bottom S/D epis 420-B, and one of the deep vias 440-D, to a backside interconnect, described in greater detail below. For clarity, operation 328 is further described with respect to FIG. 5S.

FIG. 5S is a block diagram of an example fabrication state 500S of the example semiconductor device 400 during fabrication, in accordance with some embodiments of the present disclosure. In comparison to example fabrication state 500R, the X and Y2 views of example fabrication state 500S include deep backside contacts (BSCA) 442-D in place of the removed sacrificial placeholders 418. Further, in the X and Y2 view, the deep backside contacts 442-D extend to the bottom S/D epis 420-B. However, the Y1 view is unchanged. In this way, FIG. 5S can represent the semiconductor device being fabricated after operation 328.

Referring back to FIG. 3A, at operation 330, the semiconductor device fabrication manager 150 can direct a fabrication tool to perform selective backside contact recess. Selective backside contact recess involves performing a sacrificial material overfill to form an OPL 426, and removing portions of the OPL 426. Further, selective backside contact recess involves removing the metal of predetermined backside contacts 442-D to reduce the thickness. In this way, selective backside contact recess can be useful for forming shallow backside contacts, such as shallow backside contacts 208-S described with respect to FIG. 2. For clarity, operation 330 is further described with respect to FIGS. 5T, 5U.

FIG. 5T is a block diagram of an overhead view 450T of the example semiconductor device 400 during fabrication, in accordance with some embodiments of the present disclosure. The overhead view 450T is similar to the overhead view 450M, and additionally includes deep backside contacts 442-D and shallow backside contacts 442-S (collectively referred to as backside contacts 442). For clarity, not all backside contacts are labeled. Rather, the boxes indicating backside contacts 442 also represent similar backside contacts in similar sized boxes.

FIG. 5U is a block diagram of an example fabrication state 500U of a semiconductor device, in accordance with some embodiments of the present disclosure. In comparison to example fabrication state 500S, the X, Y1, and Y2 views of example fabrication state 500U all include an OPL 426 with portions missing below the shallow backside contacts 442-S. Accordingly, view X additionally includes a shallow backside contact 442-S under the bottom S/D epi 420-B located between gate regions 454-1 and 454-2. In contrast, the Y1 view includes no other changes. However, the Y2 view additionally includes a shallow backside contact 442-S for the bottom S/D epi 420-B of device region 452-2. In this way, FIG. 5U can represent the semiconductor device being fabricated after operation 330.

Referring back to FIG. 3A, at operation 332, the semiconductor device fabrication manager 150 can direct a fabrication tool to re-fill backside ILD and CMP. Re-filling the backside ILD and CMP involves removing the remaining OPL 426, depositing an ILD layer, and performing a CMP on the deposited ILD layer. For clarity, operation 332 is further described with respect to FIG. 5V.

FIG. 5V is a block diagram of an example fabrication state 500V of a semiconductor device, in accordance with some embodiments of the present disclosure. In comparison to example fabrication state 500U, the X, Y1, and Y2 views of example fabrication state 500V additionally include ILD layer 438. In this way, FIG. 5V can represent the semiconductor device being fabricated after operation 332.

At operation 334, the semiconductor device fabrication manager 150 can direct a fabrication tool to form the backside power rail and BSPDN. Forming the backside power rail can involve fabricating the power rails in the ILD layer 438. Additionally, forming the BSPDN involves fabricating the elements of the backside interconnect such as, metallic lines and ILD material. For clarity, operation 334 is further described with respect to FIG. 5W.

FIG. 5W is a block diagram of an example fabrication state 500W of a semiconductor device, in accordance with some embodiments of the present disclosure. In comparison to example fabrication state 500V, the X, Y1, and Y2 views of example fabrication state 500W additionally include the BSPDN 446. Additionally, the X view includes a BSPR 444-VSS in contact with the bottom S/D epi 420-B located between gate regions 454-2 and 454-3. Further, the Y1 view includes three BSPR 444 (two BSPR 444-VSS and one BSPR 444-VDD). The BSPR 444-VDD is in contact with the deep via 440-D between the gate stacks. Additionally, the Y2 view includes seven BSPR 444 alternating between BSPR 444-VSS and 444-VDD. The BSPRs 444-VSS in device regions 452-1, 452-3 are in contact with the corresponding deep backside contacts 442-D. Further, the BSPR 444-VDD in device region 452-3 is in contact with the deep via 440-D, in contact with frontside contact 434-A to the top S/D epi 420-T. In this way, FIG. 5W can represent the semiconductor device being fabricated after operation 334.

For purposes of this description, certain aspects, advantages, and novel features of the embodiments of this disclosure are described herein. The disclosed processes, and systems should not be construed as being limiting in any way. Instead, the present disclosure is directed toward all novel and nonobvious features and aspects of the various disclosed embodiments, alone and in various combinations and sub-combinations with one another. The processes, and systems are not limited to any specific aspect or feature or combination thereof, nor do the disclosed embodiments require that any one or more specific advantages be present, or problems be solved.

Although the operations of some of the disclosed embodiments are described in a particular, sequential order for convenient presentation, it should be understood that this manner of description encompasses rearrangement, unless a particular ordering is required by specific language set forth below. For example, operations described sequentially can in some cases be rearranged or performed concurrently. Moreover, for the sake of simplicity, the attached figures may not show the various ways in which the disclosed processes can be used in conjunction with other processes. Additionally, the description sometimes uses terms like “provide” or “achieve” to describe the disclosed processes. These terms are high-level abstractions of the actual operations that are performed. The actual operations that correspond to these terms can vary depending on the particular implementation and are readily discernible by one of ordinary skill in the art.

As used in this application and in the claims, the singular forms “a,” “an,” and “the” include the plural forms unless the context clearly dictates otherwise. Additionally, the term “includes” means “comprises.”

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

A non-limiting list of examples are provided hereinafter to demonstrate some aspects of the present disclosure.

Example 1 is a semiconductor device. The device includes a first stacked FET, comprising: a top FET that is disposed above a bottom FET, and in electrical contact with a top source/drain epitaxial (S/D epi) and a back end of line (BEOL) interconnect; and the bottom FET, wherein the bottom FET is in electrical contact with a bottom S/D epi; a shallow backside contact that is in electrical contact with the bottom S/D epi; and a first deep via that is in electrical contact with the BEOL interconnect and the shallow backside contact, wherein the first deep via and the shallow backside contact provide a conductive path between the BEOL interconnect and the bottom S/D epi.

Example 2 includes the device of example 1, including or excluding optional features. In this example, the device includes a second deep via that is in electrical contact with a top source/drain contact and a backside power rail (BSPR). Optionally, the device includes a frontside contact between the first top FET and the BEOL interconnect.

Example 3 includes the device of any one of examples 1 to 2, including or excluding optional features. In this example, a depth of the shallow backside contact prevents a short to a backside power rail (BSPR). Optionally, the device includes a third deep via that is in electrical contact with the BEOL interconnect and the BSPR, wherein a first dielectric element isolates the third deep via from: a first gate; and a second gate. Optionally, the device includes a deep backside contact, wherein the deep backside contact is in electrical contact with the second bottom FET and the BSPR. Optionally, the device includes a gate cut region disposed between the first gate and a third gate, wherein the gate cut region is filled with bi-layer dielectrics.

Example 4 is a method for fabricating a semiconductor device, the method. The method includes forming a first backside contact placeholder by: forming a first recess under a region for a first bottom source/drain epitaxial (S/D epi), wherein a first top S/D epi is disposed above the first bottom S/D epi; and depositing a sacrificial dielectric material in the first recess; forming a first gate cut between a first gate and a second gate that surround the first bottom S/D epi and the first top S/D epi; filling the first gate cut with a bi-layer dielectric fill; forming a first deep via through an inner dielectric of the bi-layer dielectric fill, wherein the first deep via is in electrical contact with the first backside contact placeholder; removing the first backside contact placeholder; forming a shallow backside contact by: generating a first deep backside contact by filling a region previously occupied by the removed first backside contact placeholder with a conductive metal that is in electrical contact with the first deep via and the first bottom S/D epi; and recessing the first deep backside contact; and forming a back end of line (BEOL) interconnect that is in electrical contact with the first deep via, and wherein a depth of the shallow backside contact prevents a short to a backside power rail (BSPR).

Example 5 includes the method of example 4, including or excluding optional features. In this example, the bi-layer dielectric fill comprises a first dielectric and a second dielectric, wherein the first dielectric is different than the second dielectric, and wherein the second dielectric comprises the inner dielectric.

Example 6 includes the method of any one of examples 4 to 5, including or excluding optional features. In this example, forming the first deep via comprises removing the inner dielectric of the bi-layer dielectric fill, to expose the backside contact placeholder.

Example 7 includes the method of any one of examples 4 to 6, including or excluding optional features. In this example, the method includes forming a second gate cut between the second gate and a third gate, wherein the second gate cut exposes a shallow trench isolation (STI) layer disposed between the second gate and the third gate; filling the second gate cut with the bi-layer dielectric fill; forming a second deep via through the inner dielectric of the bi-layer dielectric fill, wherein the second deep via is in contact with a silicon layer disposed beneath the STI layer; performing contact patterning to expose a second top S/D epi of the second gate; forming a frontside contact that is in electrical contact with the second top S/D epi and the second deep via, wherein the formed BEOL interconnect is in electrical contact with the frontside contact; and forming the BSPR, wherein the BSPR is in electrical contact with the second deep via. Optionally, the method includes forming a third gate cut between the first gate and a fourth gate, wherein the third gate cut exposes an STI layer between the first gate and the fourth gate; and filling the third gate cut with the bi-layer dielectric fill. Optionally, the method includes forming a fourth gate cut between the fourth gate and a fifth gate, wherein the fourth gate cut exposes an STI layer between the fourth gate and the fifth gate; filling the fourth gate cut with the bi-layer dielectric fill; and forming a third deep via through the inner dielectric of the bi-layer dielectric fill, wherein the third deep via is in contact with the silicon layer disposed beneath the STI layer between the fourth gate and the fifth gate, wherein the third deep via is in electrical contact with the formed BEOL interconnect and the formed BSPR. Optionally, the method includes forming a second backside contact placeholder by: forming a second recess under a region for a second bottom S/D epi of the second gate, wherein the second bottom S/D epi is disposed beneath the second top S/D epi; and depositing the sacrificial dielectric material in the second recess; removing the second backside contact placeholder; forming a second deep backside contact by filling a region previously occupied by the removed second backside contact placeholder with the conductive metal, such that the conductive is in electrical contact with the second bottom S/D epi, and wherein the formed BSPR is in electrical contact with the second deep backside contact.

Example 8 is a computer program product comprising program instructions stored on a computer readable storage medium. The computer-readable medium includes instructions that direct the processor to forming a first backside contact placeholder by: forming a first recess under a region for a first bottom source/drain epitaxial (S/D epi), wherein a first top S/D epi is disposed above the first bottom S/D epi; and depositing a sacrificial dielectric material in the first recess; forming a first gate cut between a first gate and a second gate that surround the first bottom S/D epi and the first top S/D epi; filling the first gate cut with a bi-layer dielectric fill; forming a first deep via through an inner dielectric of the bi-layer dielectric fill, wherein the first deep via is in electrical contact with the first backside contact placeholder; removing the first backside contact placeholder; forming a shallow backside contact by: generating a first deep backside contact by filling a region previously occupied by the removed first backside contact placeholder with a conductive metal that is in electrical contact with the first deep via and the first bottom S/D epi; and recessing the first deep backside contact; and forming a back end of line (BEOL) interconnect that is in electrical contact with the first deep via, and wherein a depth of the shallow backside contact prevents a short to a backside power rail (BSPR).

Example 9 includes the computer-readable medium of example 8, including or excluding optional features. In this example, the bi-layer dielectric fill comprises a first dielectric and a second dielectric, wherein the first dielectric is different than the second dielectric, and wherein the second dielectric comprises the inner dielectric.

Example 10 includes the computer-readable medium of any one of examples 8 to 9, including or excluding optional features. In this example, forming the first deep via comprises removing the inner dielectric of the bi-layer dielectric fill, to expose the backside contact placeholder.

Example 11 includes the computer-readable medium of any one of examples 8 to 10, including or excluding optional features. In this example, the computer-readable medium includes forming a second gate cut between the second gate and a third gate, wherein the second gate cut exposes a shallow trench isolation (STI) layer disposed between the second gate and the third gate; filling the second gate cut with the bi-layer dielectric fill; forming a second deep via through the inner dielectric of the bi-layer dielectric fill, wherein the second deep via is in contact with a silicon layer disposed beneath the STI layer; performing contact patterning to expose a second top S/D epi of the second gate; forming a frontside contact that is in electrical contact with the second top S/D epi and the second deep via, wherein the formed BEOL interconnect is in electrical contact with the frontside contact; and forming the BSPR, wherein the BSPR is in electrical contact with the second deep via. Optionally, the computer-readable medium includes forming a third gate cut between the first gate and a fourth gate, wherein the third gate cut exposes an STI layer between the first gate and the fourth gate; and filling the third gate cut with the bi-layer dielectric fill. Optionally, the computer-readable medium includes forming a fourth gate cut between the fourth gate and a fifth gate, wherein the fourth gate cut exposes an STI layer between the fourth gate and the fifth gate; filling the fourth gate cut with the bi-layer dielectric fill; and forming a third deep via through the inner dielectric of the bi-layer dielectric fill, wherein the third deep via is in contact with the silicon layer disposed beneath the STI layer between the fourth gate and the fifth gate, wherein the third deep via is in electrical contact with the formed BEOL interconnect and the formed BSPR.

What is claimed is:

1. A semiconductor device comprising:
a first stacked FET, comprising:
a top FET that is disposed above a bottom FET, and in electrical contact with a top source/drain epitaxial (S/D epi) and a back end of line (BEOL) interconnect; and
the bottom FET, wherein the bottom FET is in electrical contact with a bottom S/D epi;
a shallow backside contact that is in electrical contact with the bottom S/D epi; and
a first deep via that is in electrical contact with the BEOL interconnect and the shallow backside contact, wherein the first deep via and the shallow backside contact provide a conductive path between the BEOL interconnect and the bottom S/D epi.

2. The semiconductor device of claim 1, further comprising a second deep via that is in electrical contact with a top source/drain contact and a backside power rail (BSPR).

3. The semiconductor device of claim 2, further comprising a frontside contact between the first top FET and the BEOL interconnect.

4. The semiconductor device of claim 1, wherein a depth of the shallow backside contact prevents a short to a backside power rail (BSPR).

5. The semiconductor device of claim 4, further comprising a deep backside contact, wherein the deep backside contact is in electrical contact with the second bottom FET and the BSPR.

6. The semiconductor device of claim 5, further comprising a gate cut region disposed between the first gate and a third gate, wherein the gate cut region is filled with bi-layer dielectrics.

7. The semiconductor device of claim 6, further comprising a deep frontside contact that shorts a second bottom S/D epi and a second top S/D epi.

8. A method for fabricating a semiconductor device, the method comprising:
forming a first backside contact placeholder by:
forming a first recess under a region for a first bottom source/drain epitaxial (S/D epi), wherein a first top S/D epi is disposed above the first bottom S/D epi; and
depositing a sacrificial dielectric material in the first recess;
forming a first gate cut between a first gate and a second gate that surround the first bottom S/D epi and the first top S/D epi;
filling the first gate cut with a bi-layer dielectric fill;
forming a first deep via through an inner dielectric of the bi-layer dielectric fill, wherein the first deep via is in electrical contact with the first backside contact placeholder;
removing the first backside contact placeholder;
forming a shallow backside contact by:
generating a first deep backside contact by filling a region previously occupied by the removed first backside contact placeholder with a conductive metal that is in electrical contact with the first deep via and the first bottom S/D epi; and
recessing the first deep backside contact; and
forming a back end of line (BEOL) interconnect that is in electrical contact with the first deep via, and wherein a depth of the shallow backside contact prevents a short to a backside power rail (BSPR).

9. The method of claim 8, wherein the bi-layer dielectric fill comprises a first dielectric and a second dielectric, wherein the first dielectric is different than the second dielectric, and wherein the second dielectric comprises the inner dielectric.

10. The method of claim 8, wherein forming the first deep via comprises removing the inner dielectric of the bi-layer dielectric fill, to expose the backside contact placeholder.

11. The method of claim 8, further comprising:
forming a second gate cut between the second gate and a third gate, wherein the second gate cut exposes a shallow trench isolation (STI) layer disposed between the second gate and the third gate;
filling the second gate cut with the bi-layer dielectric fill;
forming a second deep via through the inner dielectric of the bi-layer dielectric fill, wherein the second deep via is in contact with a silicon layer disposed beneath the STI layer;
performing contact patterning to expose a second top S/D epi of the second gate;
forming a frontside contact that is in electrical contact with the second top S/D epi and the second deep via, wherein the formed BEOL interconnect is in electrical contact with the frontside contact; and
forming the BSPR, wherein the BSPR is in electrical contact with the second deep via.

12. The method of claim 11, further comprising:
forming a third gate cut between the first gate and a fourth gate, wherein the third gate cut exposes an STI layer between the first gate and the fourth gate; and
filling the third gate cut with the bi-layer dielectric fill.

13. The method of claim 12, further comprising:
forming a fourth gate cut between the fourth gate and a fifth gate, wherein the fourth gate cut exposes an STI layer between the fourth gate and the fifth gate;
filling the fourth gate cut with the bi-layer dielectric fill; and
forming a third deep via through the inner dielectric of the bi-layer dielectric fill, wherein the third deep via is in contact with the silicon layer disposed beneath the STI layer between the fourth gate and the fifth gate, wherein the third deep via is in electrical contact with the formed BEOL interconnect and the formed BSPR.

14. The method of claim 13, further comprising:
forming a second backside contact placeholder by:
forming a second recess under a region for a second bottom S/D epi of the second gate, wherein the second bottom S/D epi is disposed beneath the second top S/D epi; and
depositing the sacrificial dielectric material in the second recess;
removing the second backside contact placeholder;
forming a second deep backside contact by filling a region previously occupied by the removed second backside contact placeholder with the conductive metal, such that the conductive is in electrical contact with the second bottom S/D epi, and wherein the formed BSPR is in electrical contact with the second deep backside contact.

15. A computer program product comprising program instructions stored on a computer readable storage medium, the program instructions executable by a processor to cause the processor to perform a method on a wafer, the method comprising:
forming a first backside contact placeholder by:
forming a first recess under a region for a first bottom source/drain epitaxial (S/D epi), wherein a first top S/D epi is disposed above the first bottom S/D epi; and
depositing a sacrificial dielectric material in the first recess;
forming a first gate cut between a first gate and a second gate that surround the first bottom S/D epi and the first top S/D epi;
filling the first gate cut with a bi-layer dielectric fill;
forming a first deep via through an inner dielectric of the bi-layer dielectric fill, wherein the first deep via is in electrical contact with the first backside contact placeholder;
removing the first backside contact placeholder;
forming a shallow backside contact by:
generating a first deep backside contact by filling a region previously occupied by the removed first backside contact placeholder with a conductive metal that is in electrical contact with the first deep via and the first bottom S/D epi; and
recessing the first deep backside contact; and
forming a back end of line (BEOL) interconnect that is in electrical contact with the first deep via, and wherein a depth of the shallow backside contact prevents a short to a backside power rail (BSPR).

16. The computer program product of claim 15, wherein the bi-layer dielectric fill comprises a first dielectric and a second dielectric, wherein the first dielectric is different than the second dielectric, and wherein the second dielectric comprises the inner dielectric.

17. The computer program product of claim 15, wherein forming the first deep via comprises removing the inner dielectric of the bi-layer dielectric fill, to expose the backside contact placeholder.

18. The computer program product of claim 15, the method further comprising:
forming a second gate cut between the second gate and a third gate, wherein the second gate cut exposes a shallow trench isolation (STI) layer disposed between the second gate and the third gate;
filling the second gate cut with the bi-layer dielectric fill;
forming a second deep via through the inner dielectric of the bi-layer dielectric fill, wherein the second deep via is in contact with a silicon layer disposed beneath the STI layer;
performing contact patterning to expose a second top S/D epi of the second gate;
forming a frontside contact that is in electrical contact with the second top S/D epi and the second deep via, wherein the formed BEOL interconnect is in electrical contact with the frontside contact; and
forming the BSPR, wherein the BSPR is in electrical contact with the second deep via.

19. The computer program product of claim 18, the method further comprising:
forming a third gate cut between the first gate and a fourth gate, wherein the third gate cut exposes an STI layer between the first gate and the fourth gate; and
filling the third gate cut with the bi-layer dielectric fill.

20. The computer program product of claim 19, the method further comprising:
forming a fourth gate cut between the fourth gate and a fifth gate, wherein the fourth gate cut exposes an STI layer between the fourth gate and the fifth gate;
filling the fourth gate cut with the bi-layer dielectric fill; and
forming a third deep via through the inner dielectric of the bi-layer dielectric fill, wherein the third deep via is in contact with the silicon layer disposed beneath the STI layer between the fourth gate and the fifth gate, wherein the third deep via is in electrical contact with the formed BEOL interconnect and the formed BSPR.
